(19) United States
(12) Patent Application Publication
(10) Pub. No.: US 2008/0286442 A1
(43) Pub. Date: Nov. 20, 2008

(54) LIQUID MATERIAL DISCHARGE METHOD, WIRING SUBSTRATE MANUFACTURING METHOD, COLOR FILTER MANUFACTURING METHOD, AND ORGANIC EL ELEMENT MANUFACTURING METHOD

(75) Inventors: Yoshihiko Ushiyama, Suwa (JP); Tsuyoshi Kitahara, Matsumoto (JP); Yoichi Miyasaka, Suwa (JP)

Correspondence Address: GLOBAL IP COUNSELORS, LLP, 1233 20TH STREET, NW, SUITE 700, WASHINGTON, DC, 20036-2680, US

(73) Assignee: Seiko Epson Corporation, Tokyo (JP)

(21) Appl. No.: 11/835,190

(22) Filed: Aug. 7, 2007

(30) Foreign Application Priority Data
Aug. 11, 2006 (JP) 2006-220016

(51) Int. Cl. B05D 1/02

(52) U.S. Cl. 427/8

(57) ABSTRACT

A liquid material discharge method includes positioning a substrate and a discharge head having a plurality of nozzles to face each other, discharging droplets of a liquid material including a functional material onto the substrate in synchronization with a primary scanning for moving the discharge head and the substrate in relative manner, and varying one of a discharge timing and a discharge rate for discharging the droplets from at least one of the nozzles based on landing position information of the droplets that are discharged from the nozzles.

### CROSS-REFERENCE TO RELATED APPLICATIONS

This application claims priority to Japanese Patent Application No. 2006-220016 filed on Aug. 11, 2006. The entire disclosure of Japanese Patent Application No. 2006-220016 is hereby incorporated herein by reference.

### BACKGROUND OF THE INVENTION

1. Technical Field

The present invention relates to a method for discharging a liquid material that includes a functional material, to a method for manufacturing a wiring substrate, to a method for manufacturing a color filter, and to a method for manufacturing an organic EL luminescent element.

2. Related Art

Japanese Laid-Open Patent Application Publication No. 2006-15243 discloses a method for discharging a liquid material that includes a functional material include a method for forming a desired film pattern on a substrate. This method for forming a film pattern comprises a detection step for discharging droplets of a functional material from a droplet discharge head prior to formation of the desired film pattern and detecting the landing state of the droplets; and a control processing step for detecting the discharge characteristics of the nozzles of the droplet discharge head based on the droplet landing state detected in the detection step, and creating a control signal for controlling the discharging of the droplet discharge head based on the discharge characteristics. A film pattern formation routine is also provided for forming the desired film pattern while controlling the discharging of the droplet discharge head based on the control signal. During the detection step, the solvent or dispersion medium included in the droplets, or a vapor thereof, is supplied on a stage on which the substrate is mounted. Accordingly, since the solvent or dispersion medium, or the vapor thereof, is already present on the stage, the landing state can be prevented from changing due to excessive evaporation of the solvent or dispersion medium from the landed droplets used for detection. The landing state can thus be detected more accurately, and since the discharge characteristics of the nozzles of the droplet discharge head are detected based on the landing state, the appropriate control signal can be generated in the control processing step, and a highly precise film pattern can be formed in the film pattern formation routine.

In the film pattern formation method described above, the landing position and landed diameter of the droplets are emphasized as the discharge characteristics of the nozzles of the droplet discharge head. However, there is no clear disclosure of the manner in which the control signal for driving the droplet discharge head is generated based on the detected landing position and landed diameter. Particularly when the landing position deviates due to flying deflection, the direction in which the landing position deviates due to flying deflection is not necessarily fixed, and the solution to this problem is unclear.

In such a so-called droplet discharge method (inkjet scheme), examples of possible causes of flying deflection include partial blockage of nozzles and adherence of debris or the liquid material on the periphery of the nozzle openings. Therefore, debris or the liquid material in the nozzles is removed by suction (capping), debris is wiped off the surface of the nozzle plate in which the nozzles are formed (wiping), and other restoration operations (refresh operations) for restoring the droplet discharge head are performed in order to prevent flying deflection. However, the causes of flying deflection cannot be eliminated even by such restoration operations, and there remains a risk of flying deflection.

In view of the above, it will be apparent to those skilled in the art from this disclosure that there exists a need for an improved liquid material discharge method. This invention addresses this need in the art as well as other needs, which will become apparent to those skilled in the art from this disclosure.

### SUMMARY

The present invention was developed in view of the foregoing problems, and an advantage of the present invention is to provide a liquid material discharge method capable of controlling the driving of a discharge head to cause droplets to land with satisfactory precision, and to provide a wiring board manufacturing method, a d color filter manufacturing method, and an organic EL luminescent element manufacturing method that apply the liquid material discharge method.

According to one aspect of the present invention, a liquid material discharge method is arranged for positioning a substrate and a discharge head that has a plurality of nozzles so as to face each other, and discharging droplets of a liquid material that includes a functional material onto the substrate in synchronization with primary scanning for moving the discharge head and the substrate in relative manner, wherein the liquid material discharge method comprises a discharge step for varying the discharge timing for a prescribed nozzle among the plurality of nozzles and discharging based on landing position information of the droplets that are discharged from the plurality of nozzles.

According to this method, the discharge timing for a prescribed nozzle among the plurality of nozzles is varied, and the liquid material is discharged based on landing position information of the droplets that are discharged from the plurality of nozzles. Accordingly, a prescribed nozzle for which the landing position must be corrected is specified, and the discharge timing of the other nozzles is varied based on the abovementioned landing position information, whereby the droplets can be landed with satisfactory precision.

The liquid material discharge method according to one aspect of the present invention further includes a step for driving the discharge head and acquiring the landing position information of the droplets that are discharged from the plurality of nozzles. According to this method, since a step is provided for acquiring the landing position information, the newest landing position information is acquired and can be reflected in the discharge step.

The liquid material discharge method according to one aspect of the present invention further includes an arrangement pattern generation step for generating a second arrangement pattern in which the flying (falling) deflection (deviation in trajectory of the droplet) is corrected in the direction of the primary scanning based on the landing position information for a first arrangement pattern for arranging the droplets on the substrate through the primary scanning, and, in the discharge step, the discharge timing is varied for a nozzle in which flying deflection occurs based on the second arrangement pattern, and the droplets are discharged.

According to this method, in the discharge step, the discharge timing is varied for a nozzle in which flying deflection occurs based on the second arrangement pattern that was corrected in the arrangement pattern generation step, and the droplets are discharged. Accordingly, a first arrangement pattern is generated that takes into account the wetting properties and other physical properties of the droplets with respect to the substrate, the drawing precision of the droplet discharge device that has the discharge head, and other characteristics in advance, and a second arrangement pattern is generated in which the flying deflection is corrected for the first arrangement pattern. The landing positions of the droplets can thereby be controlled with high precision at least in the primary scanning direction.

In a preferred configuration, the second arrangement pattern is generated for a reverse movement and a forward movement in the primary scanning, and the correction of the flying deflection in the primary scanning direction is performed differently for the reverse movement and the forward movement in the arrangement pattern generation step. According to this method, since the second arrangement pattern is generated with consideration for fluctuation in the landing positions due to the reverse movement and the forward movement in the primary scanning, the landing positions of the droplets can be controlled with higher precision.

The liquid material discharge method according to one aspect of the present invention is also a method wherein the correction of the discharge timing in the primary scanning direction for the flying deflection is performed in units of discharge resolution at which the droplets are discharged on the substrate. According to this method, the discharge timing is corrected in units of discharge resolution, and the discharge can therefore be controlled with high precision.

The correction of the discharge timing in the primary scanning direction for the flying deflection may also be performed in units of movement resolution of a movement mechanism for moving the substrate in the primary scanning direction. According to this method, the discharge timing is corrected in units of movement resolution, and the discharge can therefore be controlled with high precision.

Another aspect of the present invention is the liquid material discharge method for positioning a substrate and a discharge head that has a plurality of nozzles so as to face each other, and discharging droplets of a liquid material that includes a functional material onto the substrate in synchronization with primary scanning for moving the discharge head and the substrate in relative manner, wherein the liquid material discharge method comprises a discharge step for varying the discharge rate for a prescribed nozzle among the plurality of nozzles and discharging based on landing position information of the droplets that are discharged from the plurality of nozzles.

According to this method, the discharge rate for a prescribed nozzle among the plurality of nozzles is varied, and the liquid material is discharged based on landing position information of the droplets that are discharged from the plurality of nozzles. Accordingly, the droplets can be landed with satisfactory precision by specifying a prescribed nozzle for which the landing position must be corrected, and varying the discharge rate of the other nozzles based on the landing position information.

The liquid material discharge method according to one aspect of the present invention further includes a step for driving the discharge head and acquiring the landing position information of the droplets that are discharged from the plurality of nozzles. According to this method, since a step is provided for acquiring the landing position information, the newest landing position information is acquired and can be reflected in the discharge step.

The liquid material discharge method according to one aspect of the present invention further includes an arrangement pattern generation step for generating a second arrangement pattern in which the flying deflection is corrected in the direction of the primary scanning based on the landing position information for a first arrangement pattern for arranging the droplets on the substrate through the primary scanning, and, in the discharge step, the discharge rate is varied for a nozzle in which flying deflection occurs based on the second arrangement pattern, and the droplets are discharged.

According to this method, in the discharge step, the discharge rate is varied for a nozzle in which flying deflection occurs based on the second arrangement pattern that was corrected in the arrangement pattern generation step, and the droplets are discharged. Accordingly, a first arrangement pattern is generated that takes into account the wetting properties and other physical properties of the droplets with respect to the substrate, the drawing precision of the droplet discharge device that has the discharge head, and other characteristics in advance, and a second arrangement pattern is generated in which the flying deflection is corrected for the first arrangement pattern. The landing positions of the droplets can thereby be controlled with high precision at least in the primary scanning direction.

In a preferred configuration, the second arrangement pattern is generated for the reverse movement and the forward movement in the primary scanning, and the correction of the flying deflection in the primary scanning direction is performed differently for the reverse movement and the forward movement in the arrangement pattern generation step. According to this method, since the second arrangement pattern is generated with consideration for fluctuation in the landing positions due to the reverse movement and the forward movement in the primary scanning, the landing positions of the droplets can be controlled with higher precision.

The liquid material discharge method according to one aspect of the present invention is arranged such that a plurality of discharge regions is partitioned by partition wall parts on the substrate, and the discharge timing is varied and discharge is performed in the discharge step so that at least a portion of the droplets discharged from a nozzle in which flying deflection occurs based on the landing position information do not land on the partition wall parts, or so that the droplets do not land in the vicinity of the partition wall parts.

The liquid material discharge method according to one aspect of the present invention is arranged such that a plurality of discharge regions is partitioned by partition wall parts on the substrate, and the discharge rate is varied and discharge is performed in the discharge step so that at least a portion of the droplets discharged from a nozzle in which flying deflection occurs based on the landing position information do not land on the partition wall parts, or so that the droplets do not land in the vicinity of the partition wall parts.

According to these methods, control can be performed so that the necessary quantity of droplets always lands in each discharge region that is partitioned by the partition wall parts.

The wiring substrate manufacturing method according to one aspect of the present invention is a method for manufacturing a wiring substrate that has wiring composed of a conductive material on a substrate, wherein the method comprises a drawing step for using the liquid material discharge method for discharging and drawing using droplets of a liquid material that includes a conductive material on the substrate, and a drying and baking step for drying and baking the discharged and drawn liquid material to form the wiring.

According to this method, since the liquid material discharge method of the present invention is used in the drawing step, the landing positions of the droplets discharged from the nozzle can be corrected, and the droplets of the liquid material that includes a conductive material can be landed with satisfactory precision even when there is a nozzle for which flying deflection occurs. Wiring can thereby be formed that has a stable shape after drying and baking. Specifically, it is possible to manufacture a wiring substrate that has extremely fine wiring.

The color filter manufacturing method according to one aspect of the present invention is a method for manufacturing a color filter that has color layers in at least three colors in a plurality of color regions partitioned by partition wall parts on a substrate; and the method for manufacturing a color filter comprises a drawing step for using the liquid material discharge method for discharging and drawing using droplets of at least three colors of a liquid material that includes a color-layer-forming material on the plurality of color regions, and a drying step for drying the discharged and drawn liquid material to form at least three colors of the color layers.

According to this method, since the liquid material discharge method of the present invention is used in the drawing step, the landing positions of the droplets discharged from the nozzle can be corrected, and the droplets of the liquid material that includes a color-layer-forming material can be landed with satisfactory precision even when there is a nozzle for which flying deflection occurs. Uneven discharge or color mixing due to flying deflection can thereby be reduced. Specifically, it is possible to manufacture a color filter that has stable quality and minimal unevenness of color.

The organic EL element manufacturing method according to one aspect of the present invention is a method for manufacturing an organic EL element that has organic EL luminescent layers in a plurality of luminescent layer formation regions partitioned by partition wall parts on a substrate; and the method for manufacturing an organic EL element comprises a drawing step for using the liquid material discharge method for discharging and drawing using droplets of a liquid material that includes at least a luminescent-layer-forming material on the plurality of luminescent layer formation regions, and a drying step for drying the discharged and drawn liquid material to form the organic EL luminescent layers.

According to this method, since the liquid material discharge method of the present invention is used in the drawing step, the landing positions of the droplets discharged from the nozzle can be corrected, and the droplets of the liquid material that includes a luminescent-layer-forming material can be made to land with satisfactory precision even when there is a nozzle for which flying deflection occurs. Uneven discharge or color mixing due to flying deflection can thereby be reduced. Specifically, it is possible to manufacture an organic EL element that has stable quality and minimal unevenness in luminescence or luminance.

These and other objects, features, aspects and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is a schematic perspective view showing the structure of the droplet discharge device;

FIG. 2A is a schematic diagram showing the positions of the droplet discharge heads in relation to the carriage;

FIG. 2B is a diagram showing the positioning of the nozzles;

FIG. 3A is a schematic exploded perspective view showing the structure of the droplet discharge heads;

FIG. 3B is a sectional view showing the structure of the nozzle parts;

FIG. 4 is a block diagram showing the electrical configuration of the droplet discharge device;

FIGS. 5A and 5B are diagrams showing the control signals for discharge control, wherein FIG. 5A shows an example of the control of discharge timing, and FIG. 5B shows an example of the control of discharge rate;

FIG. 6 is a schematic plan view showing the wiring substrate;

FIG. 7 is a flowchart showing the wiring substrate manufacturing method;

FIGS. 8A and 8B are diagrams showing the method for detecting the droplet landing positions;

FIG. 9A is a diagram showing the bit map;

FIG. 9B is a diagram showing the corrected bit map of FIG. 9A;

FIG. 10 is a schematic exploded perspective view showing the structure of the liquid crystal display device;

FIG. 11 is a schematic plan view showing the arrangement of the droplet discharge heads with respect to the carriage;

FIGS. 12A through 12E are schematic sectional views showing the color filter manufacturing method;

FIG. 13 is a schematic sectional view showing the structure of the organic EL display device; and

FIGS. 14A through 14F are schematic sectional views showing the method for manufacturing a luminescent element part as the organic EL element.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

In the present embodiment, the liquid material discharge method for using a droplet discharge device capable of discharging droplets of a liquid material to discharge onto and draw on a substrate using a liquid material that includes a functional material will be described using the wiring substrate manufacturing method, the color filter manufacturing method, and the organic EL element manufacturing method as examples. The drawings used in the description do not show actual dimensions, and the dimensions therein are reduced or enlarged as appropriate.

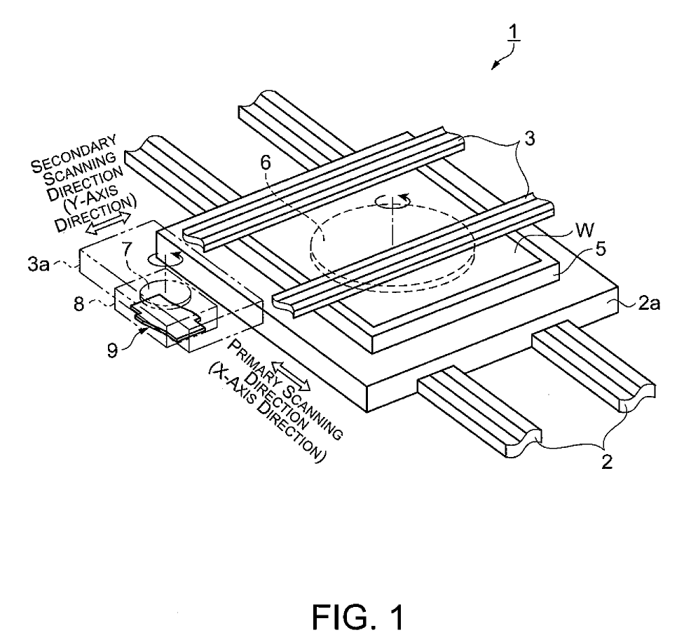

The droplet discharge device will first be described based on FIGS. 1 through 5. FIG. 1 is a schematic perspective view showing the structure of the droplet discharge device.

As shown in FIG. 1, the droplet discharge device 1 is provided with a pair of guide rails 2, and a primary scanning stage 2a for moving in the primary scanning direction (X-axis direction) through the use of an air slider and a linear motor (not shown) provided inside the guide rails 2. A pair of guide rails 3 provided orthogonal to the guide rails 2 is provided above the guide rails 2, and a secondary scanning stage 3a is provided for moving along the secondary scanning direction through the use of an air slider and a linear motor (not shown) provided inside the guide rails 3.

A setting table 5 for mounting a substrate W as the discharge object is provided on the primary scanning stage 2a via a θ table 6. The setting table 5 is configured so as to be capable of attaching and fixing the substrate W, and a reference axis in the substrate W can be properly aligned with the primary scanning direction and the secondary scanning direction through the use of the θ table 6.

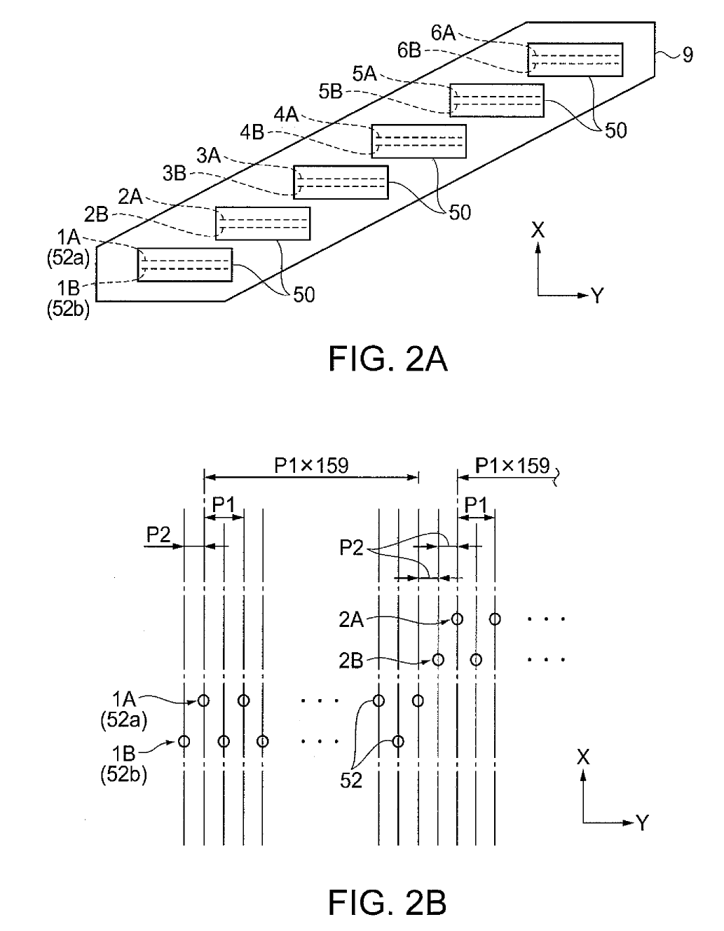

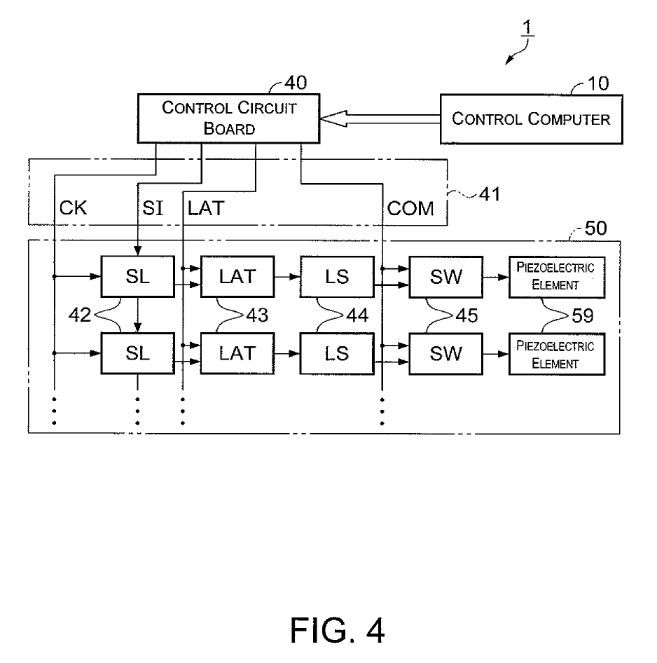

The secondary scanning stage 3a is provided with a carriage 8 that is attached by suspension via a rotation mechanism 7. The carriage 8 is provided with a head unit 9 that is provided with a plurality of droplet discharge heads 50 (see FIGS. 2A and 2B); a liquid material feeding mechanism (not shown) for supplying the liquid material to the droplet discharge heads 50; and a control circuit board 40 (see FIG. 4) for electrically controlling the driving of the droplet discharge heads 50.

A linear scale (not shown) is provided along the guide rails 2. An encoder (not shown) is attached to the primary scanning stage 2a in a position facing the linear scale. In this case, the encoder generates pulses in units of 0.1 μm according to the linear scale. The movement of the setting table 5 in the X-axis direction can thereby be controlled forward movement resolution units of 0.1 μm.

Besides the structures described above, a maintenance mechanism for eliminating nozzle obstructions in the plurality of droplet discharge heads 50 mounted in the head unit 9, removing debris or contamination from the nozzle surfaces, and performing other maintenance is provided in a position facing the plurality of droplet discharge heads 50, but is not shown in the drawings.

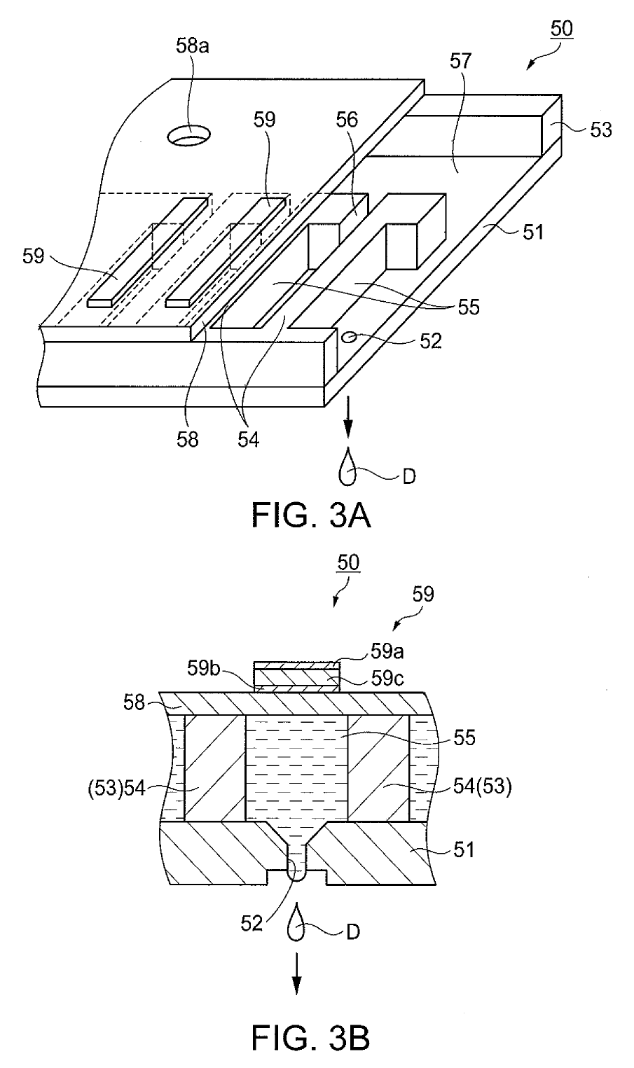

The droplet discharge heads 50 mounted in the head unit 9 will next be described based on FIGS. 2A, 2B and 3. FIG. 2A is a schematic diagram showing the positions of the droplet discharge heads in relation to the head unit, and FIG. 2B is a diagram showing the positioning of the nozzles.

As shown in FIG. 2A, the droplet discharge heads 50 have so-called double nozzle rows 52a, 52b. The two nozzle rows 52a, 52b are offset in the Y-axis direction so as to partially overlap each other as viewed in the X-axis direction (primary scanning direction), and six droplet discharge heads 50 are mounted in the head unit 9 parallel to the X-axis direction.

As shown in FIG. 2B, in this case, the two nozzle rows 52a, 52b are each composed of 180 nozzles 52 that are arranged at equal intervals P1. The nozzle diameter is approximately 20 μm, and the equal interval P1 is approximately 140 μm. Due to fluctuation in the discharged amount, the ten nozzles 52 at both ends of the nozzle rows 52a, 52b are not used. The six droplet discharge heads 50 are positioned so that the portions corresponding to the sets of ten nozzles 52 overlap each other when viewed from the X-axis direction. In a single droplet discharge head 50, one nozzle row 52a is provided so as to be offset with respect to the other nozzle row 52b by a nozzle pitch P2 that is half the equal interval P1. The effective nozzle count of each nozzle row 52a, 52b is thus 160, and 320 nozzles 52 are arranged at the nozzle pitch P2 as viewed from the X-axis direction. Furthermore, the six droplet discharge heads 50 are arranged in the head unit 9 so that the 320 nozzles 52 are arranged at the nozzle pitch P2 as viewed from the X-axis direction. Accordingly, the droplets can be landed at equal intervals in the Y-axis direction when droplets are discharged from the nozzles 52 of the six droplet discharge heads 50 during principal scanning in which the head unit 9 and the substrate W are positioned facing each other and moved relative to each other in the X-axis direction.

FIG. 3A is a schematic exploded perspective view showing the structure of the droplet discharge heads, and FIG. 3B is a sectional view showing the structure of the nozzle parts. As shown in FIGS. 3A and 3B, the droplet discharge heads 50 have a structure in which a nozzle plate 51 having a plurality of nozzles 52 from which droplets D are discharged; a cavity plate 53 having barriers 54 for partitioning cavities 55 with which the plurality of nozzles 52 communicates; and an oscillation plate 58 having transducers 59 that correspond to the plurality of cavities 55 are layered in sequence and joined together.

The cavity plate 53 has the barriers 54 for partitioning the cavities 55 with which the nozzles 52 communicate, and has channels 56, 57 for filling the liquid material into the cavities 55. The channel 57 is between the nozzle plate 51 and the oscillation plate 58, and the space thus formed serves as a reservoir in which the liquid material is stored.

The liquid material is fed through a conduit from the liquid material feeding mechanism and through a feeding hole 58a provided to the oscillation plate 58, and is stored in the reservoir. The liquid material is then filled into the cavities 55 through the channels 56.

As shown in FIG. 3B the transducers 59 are piezoelectric elements composed of a piezo element 59c and a pair of electrodes 59a, 59b that sandwich the piezo element 59c. A drive voltage pulse is applied to the pair of electrodes 59a, 59b from the outside, whereby the bonded oscillation plate 58 is caused to change shape. The volume of the cavities 55 divided by the barriers 54 thereby increases, and the liquid material is drawn into the cavities 55 from the reservoir. When application of the drive voltage pulse is ended, the oscillation plate 58 returns to the original state and presses on the filled liquid material. This structure thereby enables the liquid material to be discharged as droplets D. The discharging of the liquid material can be controlled for each of the nozzles 52 by controlling the drive voltage pulse that is applied to the piezo element 59c. For example, the droplet discharge amount, the discharge timing, the discharge rate, and other characteristics can be controlled. Discharge control will be described in detail hereinafter.

The droplet discharge heads 50 are not limited to being provided with piezoelectric elements (piezo elements). The droplet discharge heads 50 may be provided with an electromechanical conversion element for displacing the oscillation plate 58 through electrostatic adsorption, or an electrothermal conversion element for heating the liquid material and discharging the liquid material from the nozzles 52 as droplets D.

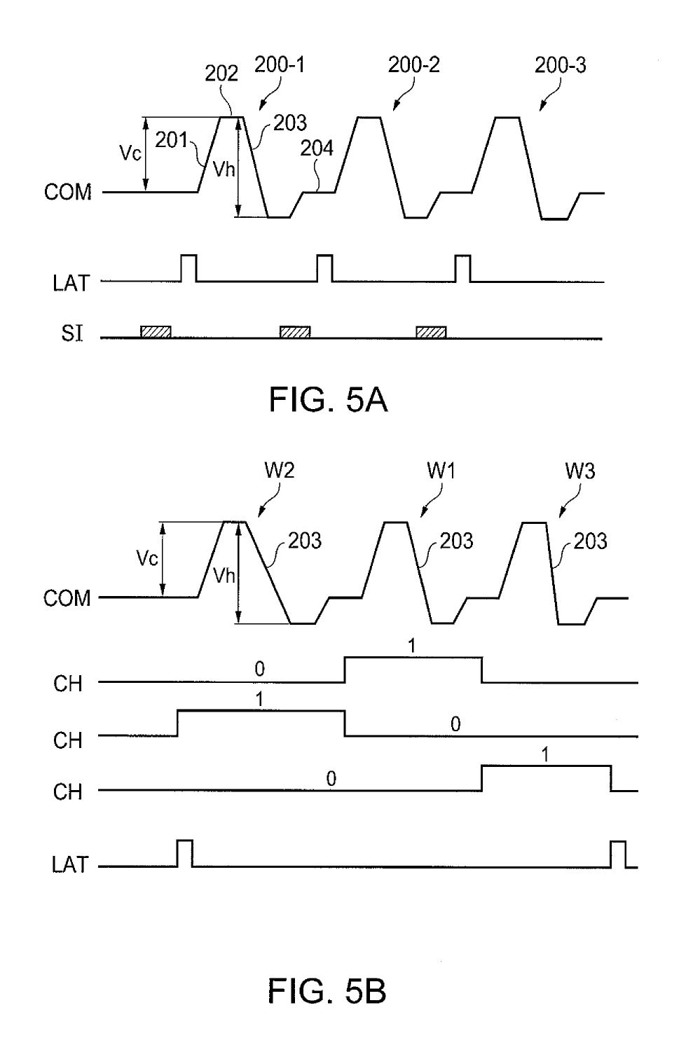

The method for controlling discharge in the droplet discharge heads will next be described with reference to FIGS. 4 and 5. FIG. 4 is a block diagram showing the electrical configuration of the droplet discharge device. The droplet discharge device 1 is provided with a control computer 10 for performing overall control of the entire device, and a control circuit board 40 for performing electrical drive control of the plurality of droplet discharge heads 50. The control circuit board 40 is electrically connected with the droplet discharge heads 50 via a flexible cable 41. The droplet discharge heads 50 are also provided with a shift register (SL) 42, a latch circuit (LAT) 43, a level shifter (LS) 44, and a switch (SW) 45 that correspond to a piezoelectric element 59 that is provided to each nozzle 52 (see FIGS. 3A and 3B).

Discharge control in the droplet discharge device 1 is performed in the following manner. Specifically, the control computer 10 first transfers bit map data (specifically described hereinafter) in which an arrangement pattern of the liquid material on the substrate W (see FIG. 1) is digitized to the control circuit board 40. The control circuit board 40 then decodes the bit map data to generate nozzle data as ON/OFF (discharge/no discharge) information for each nozzle 52. The nozzle data are converted to serial signals (SI), synchronized with a clock signal (CK), and transferred to the shift registers 42.

The nozzle data transferred to the shift registers 42 are latched at the timing at which the latch signals (LAT) are inputted to the latch circuits 43, and the nozzle data are converted by the level registers 44 to gate signals used for the switches 45. Specifically, when the nozzle data indicate “ON,” the switches 45 open and drive signals (COM) are fed to the piezoelectric elements 59, and when the nozzle data indicate “OFF,” the switches 45 are closed, and the drive signals (COM) are not fed to the piezoelectric elements 59. The liquid material is converted to droplets and discharged from nozzles 52 that correspond to “ON,” and the discharged liquid material is arranged on the substrate W.

Such discharge control is periodically performed as shown in FIGS. 5A and 5B in synchronization with the relative movement (primary scanning) of the head unit 9 and the substrate W.

FIGS. 5A and 5B are diagrams showing the control signals for discharge control, wherein FIG. 5A shows an example of the control of discharge timing, and FIG. 5B shows an example of the control of discharge rate.

In the drive signal (COM) as shown in FIG. 5A, a sequence of pulse groups 200-1, 200-2, . . . that have an electrical discharge pulse 201, a charging pulse 202, and an electrical discharge pulse 203 are connected by an intermediate potential 204. A single droplet is discharged by a single pulse group in the manner described below.

Specifically, the potential level is increased, and the liquid material is drawn into the cavities 55 (see FIG. 3B) by the electrical discharge pulse 201. The liquid material inside the cavities 55 is then rapidly pressurized and expelled in the form of droplets (discharge) from the nozzles 52 by the sharp charging pulse 202. Lastly, the reduced potential level is returned to the intermediate potential 204 by the electrical discharge pulse 203, and the pressure oscillation (natural oscillation) generated inside the cavities 55 by the charging pulse 202 is cancelled.

The voltage components Vc, Vh, the time component (pulse slope, connection gap between pulses, and the like), and the like in the drive signal (COM) are parameters that have a significant bearing on the discharged amount, the discharge stability, and other factors, and these parameters require appropriate advance design. In this case, the period of the latch signal (LAT) is set to 20 kHz with consideration for the specific frequency characteristics of the droplet discharge heads 50. The speed (in this case, the movement speed of the setting table 5 in the X-axis direction) of relative movement of the droplet discharge heads 50 and the substrate W during primary scanning is set to 200 mm/second. Accordingly, when the discharge resolution is calculated by dividing the relative movement speed by the latch period, the unit of discharge resolution is 10 μm. Specifically, the discharge timing can be set for each nozzle 52 in units of discharge resolution. When the timing at which the latch pulse is generated is based on a pulse that is outputted by the encoder provided to the primary scanning stage 2a, the discharge timing can also be controlled in units of movement resolution.

Discharge control is not limited to controlling only the discharge timing. For example, the droplet discharge rate can be varied by varying the slope of the electrical discharge pulse 203 of the drive signal. Specifically, the steeper the slope of the electrical discharge pulse 203, the greater the increase in the discharge rate. Since a change in the discharge rate is accompanied by a change in the discharged amount of droplets, the voltage components Vc, Vh must be set with consideration for the physical properties (viscosity and other properties) of the liquid material in order to maintain a constant discharge amount. The discharge rate can also be changed by varying the charging time of the charging pulse 202 and the potential of the intermediate potential 204.

For example, as shown in FIG. 5B, a reference drive signal W1, and two drive signals W2, W3 in which the slope of the electrical discharge pulse 203 is varied in relation to the drive signal W1 are generated in a single latch period. Specifically, the relationship between the drive signals W1, W2, W3 and the corresponding discharge rates V1, V2, V3 is V2<V1<V3. A channel signal (CH) that corresponds to each drive signal W1, W2, W3 is generated and transmitted to the level registers 44, whereby a drive signal (COM) having a different discharge rate can be selected in accordance with an “ON” nozzle data signal, and the droplets can be discharged.

Such a droplet discharge device 1 makes it possible to position the head unit 9 and the substrate W so as to face each other, and discharge a liquid material that includes a functional material with high positional precision from the six droplet discharge heads 50 provided to the head unit 9 in synchronization with primary scanning by the primary scanning stage 2a. The liquid material can be discharged as droplets with varying discharge amounts, discharge timings, and discharge rates by each nozzle 52 of the droplet discharge heads 50. Accordingly, when there is a nozzle 52 in which flying (falling) deflection (deviation in trajectory of the droplet) occurs, for example, that is not restored by maintenance of the droplet discharge heads 50 by the maintenance mechanism, deviation of the landing position due to flying deflection can be corrected by changing the method of discharge control for the affected nozzle 52. The replacement frequency of the droplet discharge head 50 that has the affected nozzle 52 can thereby be reduced.

### FIRST EMBODIMENT

### Liquid Material Discharge Method and Wiring Substrate Manufacturing Method

The liquid material discharge method of the present invention will next be described using the example of the wiring board manufacturing method in which the liquid material discharge method is applied.

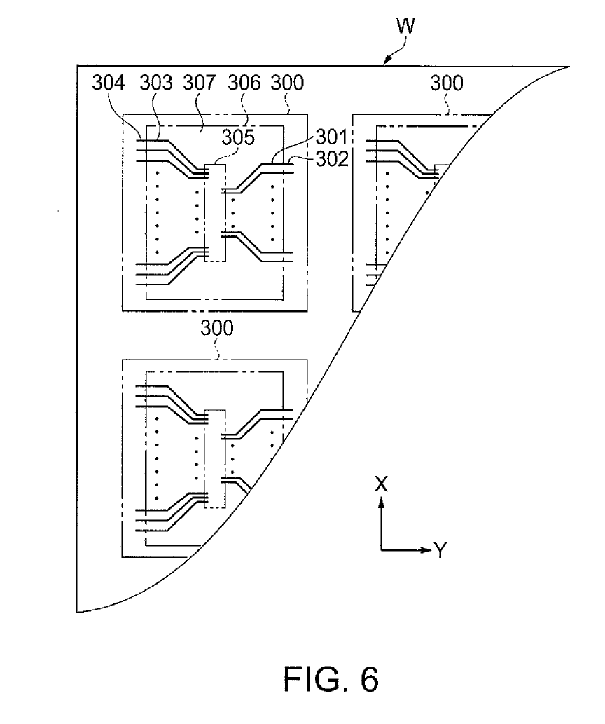

FIG. 6 is a schematic plan view showing the wiring substrate. As shown in FIG. 6, the wiring substrate 300 is a circuit substrate for planar packaging of a semiconductor device (IC), and is composed of an insulation film 307, and input wiring 301 and output wiring 303 composed of a conductive material that is arranged to correspond to input and output electrodes (bumps) of the IC. The insulation film 307 is formed clear of the input terminal parts 302 and the output terminal parts 304, and covers the plurality of input wiring 301 and output wiring 303 so that the input wiring 301 and the output wiring 303 are each partially exposed in the packaging region 305. The wiring substrates 300 are formed in a matrix as work pieces on the substrate W, and are retrieved by dividing the substrate W. A rigid glass substrate as an insulation substrate, a ceramic substrate, or a glass epoxy resin substrate, as well as a flexible resin substrate may be used as the substrate W. Scribing, dicing, laser cutting, pressing, and other methods may be selected as the dividing method according to the material used as the substrate W.

In the present embodiment, an insulation film composed of an insulation material, or wiring composed of a conductive material is formed by a droplet discharge method that uses the droplet discharge device 1. The aim is to form wiring or an insulation film without waste of materials. Compared to a photolithography method, since there is no need for an exposure mask, development, etching, or other processes to form the pattern, the process can be simplified regardless of the size of the substrate W.

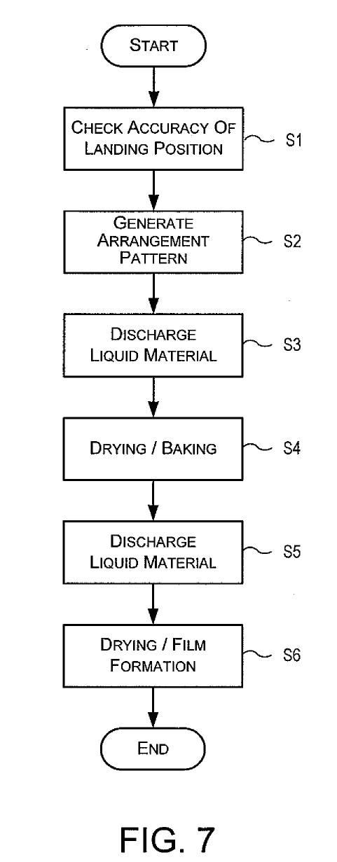

FIG. 7 is a flowchart showing the wiring substrate manufacturing method. The wiring substrate manufacturing method of the present embodiment is provided with a checking step (step S1) for driving the droplet discharge heads 50 as discharge heads and acquiring information relating to the landing positions of the droplets D of the liquid material that includes the conductive material discharged by each of the plurality of nozzles 52. The wiring substrate manufacturing method is also provided with an arrangement pattern generation step (step S2) for generating corrected bitmap data as a second arrangement pattern in which flying deflection is corrected in the primary scanning direction based on the landing position information for the bit map data as the first arrangement pattern for arranging the droplets D on the substrate W through primary scanning; a discharge step (step S3) for discharging at a different discharge timing for a nozzle 52 in which flying deflection of the droplets D occurs among the plurality of nozzles 52 based on the corrected bit map data; and a drying and baking step (step S4) for drying and baking the discharged and drawn liquid material to form wiring 301, 303. There are also provided a step for discharging from the droplet discharge heads 50 a liquid material that includes an insulation material onto the substrate on which the wiring 301, 303 is formed (step S5), and a step (step S6) for drying and forming a film from the discharged liquid material.

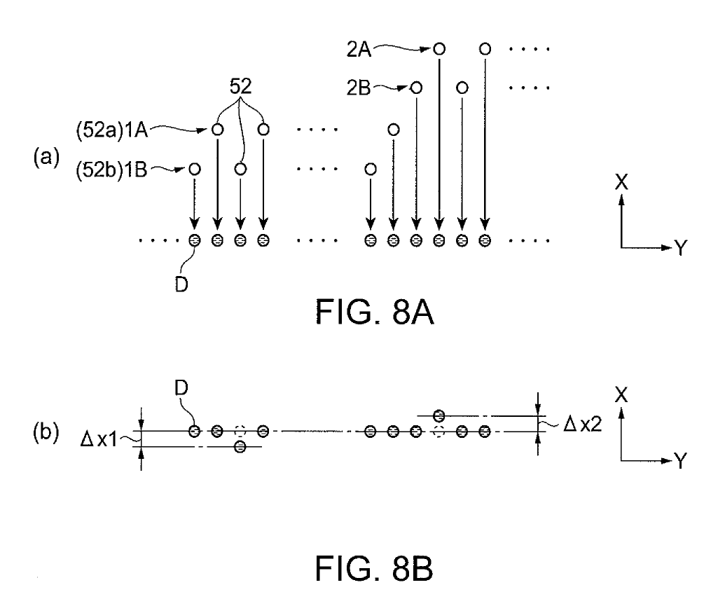

The checking step (step S1) will first be described. FIGS. 8A and 8B are diagrams showing the method for detecting the landing positions of the droplets. In the checking step of step S1, the landing positions of the droplets D discharged from all of the nozzles 52 of all of the droplet discharge heads 50 mounted in the head unit 9 are detected.

As shown in FIGS. 2A and 2B, six droplet discharge heads 50 are arranged in the head unit 9 so as to be offset from each other at a prescribed interval in the X-axis direction. In step S1, droplets D are discharged toward a recording paper mounted on the setting table 5 from all of the nozzles 52 of nozzle rows 1A, 1B through nozzle rows 6A, 6B of the plurality of (six) droplet discharge heads 50, as shown in FIG. 8A. At this time, the primary scanning stage 2a is moved so that the recording paper moves in the primary scanning direction (X-axis direction) with respect to the head unit 9 based on the position information of the six droplet discharge heads 50 provided in the head unit 9. The discharge timing is also controlled for each nozzle row so that the discharged droplets D land in a substantially straight line in the Y-axis direction of the recording paper.

When flying deflection occurs in a nozzle 52, the droplets D discharged from the affected nozzle 52 land, for example, in positions that are offset by Δ×1 or Δ×2 in the X-axis direction from the abovementioned straight line, as shown in FIG. 5B.

The values (deviation amounts) of Δ×1 and Δ×2 are acquired as landing position information by capturing an image of the landed droplets D on the recording paper using a camera that is provided with a CCD or other imaging element, and using the control computer 10 to process the captured image information.

Even when the discharge timing is controlled for each nozzle row by the control computer 10, not all of the droplets D discharged from the nozzles 52 necessarily land in the straight line. The landing positions may deviate particularly where the nozzle rows change. As a more specific detection method, the imaging range of the abovementioned camera may allow imaging of the landing position that corresponds to at least one droplet discharge head 50. The abovementioned straight line is specified by image processing from the image information captured for each droplet discharge head 50, and the amount of deviation from the straight line in the primary scanning direction is computed for each nozzle 52 as landing position information. Alternatively, a nozzle 52 that corresponds to droplets D whose landing deviation is equal to or greater than a prescribed value may be specified as the landing position information. The abovementioned camera is gradually offset in the Y-axis direction to capture an image of the state of the droplets D landed on the recording paper, whereby landing position information is acquired for all the droplet discharge heads 50 mounted in the head unit 9. The same operation is performed when a plurality of head units 9 is provided. The camera is also not limited to a single unit, and a plurality of cameras may be arranged so that each can move in the Y-axis direction, and the processing may be dispersed.

In this case, the landing positions of the droplets D shown in FIG. 8B are offset in the primary scanning direction (X-axis direction), but the droplets D dispersed from nozzles 52 in which flying deflection occurs do not necessarily fly in the same direction. In the present embodiment, since the same type of liquid material is discharged from each of the droplet discharge heads 50, even if the landing positions were to deviate in the Y-axis direction, the effect on drawing of the liquid material is essentially small. The correction described hereinafter can thus be performed effectively by detecting the amount of deviation in the primary scanning direction.

In this case, the droplet discharge heads 50 and the substrate W are spaced apart and positioned so as to face each other, and the liquid material is discharged in synchronization with the back and forth movement of the substrate W with respect to the droplet discharge heads 50. Consequently, the amount of deviation in the primary scanning direction changes according to whether the direction of flying deflection is forward or backward according to the forward movement and the reverse movement. Therefore, the recording operation for landing the droplets D on the recording paper is divided into a forward movement and a reverse movement in the same manner as the primary scanning, the landing states in each movement are imaged, and the landing position information is acquired. The process then proceeds to step S2.

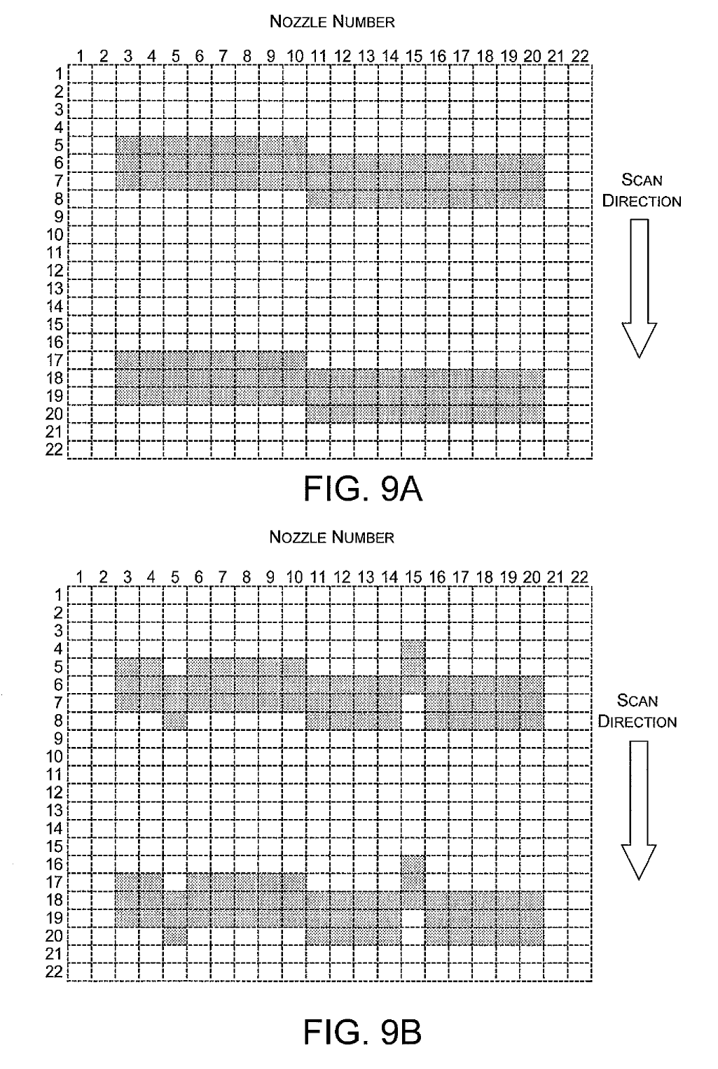

Step S2 in FIG. 7 is the arrangement pattern generation step. FIG. 9A is a diagram showing the original bit map data, and FIG. 9B is a diagram showing the corrected bit map data.

As shown in FIG. 9A, the nozzle numbers of a plurality of nozzle rows in the primary scanning are the horizontal axis, and the units of discharge resolution in the primary scanning are the vertical axis, for example. The regions partitioned by the vertical axis and the horizontal axis indicate arrangement regions in which the droplets D are arranged. In this case, the halftone regions are the original bit map data that are created based on CAD data for the wiring substrate 300. FIG. 9A shows a portion of the data. The spreading of the droplets D landed on the substrate W, the drawing precision of the droplet discharge device 1, and other factors are taken into account to determine the position and number of the arrangement regions. The vertical axis may define the arrangement regions in units of the output pulses of an encoder, as previously mentioned.

As shown in FIG. 9B, in step S27 the control computer 10 generates corrected bit map data in which the flying deflection is corrected based on the landing position information acquired in step S1 for the original bit map data stored in memory. As previously described, the data are generated for the forward movement and the reverse movement of the primary scanning. The positions of the arrangement regions for the droplets D of the affected nozzle 52 are offset according to the amount of deviation due to flying deflection. The process then proceeds to step S3.

Step S3 of FIG. 7 is the liquid material discharge step. In step S3, a liquid material that includes a conductive material is filled into the droplet discharge heads 50, the control computer 10 controls the primary scanning stage 2a and the secondary scanning stage 3a to cause the head unit 9 and the substrate W to move relative to each other, and the plurality of droplet discharge heads 50 mounted in the head unit 9 is driven. In this primary scanning, the control computer 10 causes discharge to occur at a different discharge timing for a nozzle 52 in which flying deflection of the droplets D occurs among the plurality of nozzles 52 based on the corrected bit map data. Specifically, the droplets D are essentially landed in the correct positions by selecting a latch signal (LAT) whereby the droplets D are arranged in a corrected arrangement region, and discharging the droplets D. The liquid material is thereby discharged and drawn in a pattern that corresponds to the wiring 301, 303 on the substrate W.

Examples of the conductive material included in the liquid material include metal particles including at least any one of gold, silver, copper, aluminum, palladium, and nickel, as well as oxides of these metals; and conductive polymers, superconductor particles, and the like are also used. These conductive particles may be coated on the surface with an organic substance or the like to enhance dispersion properties for use. The grain size of the conductive particles is preferably from 1 nm to 1.0 μm. There is a risk of blockage of the nozzles 52 of the droplet discharge heads 50 when the grain size is larger than 1.0 μm. When the grain size is less than 1 nm, the volume ratio of the coating agent with respect to the conductive particles increases, and the ratio of the organic substance in the resultant film is excessive.

The dispersion medium is not particularly limited insofar as it is capable of dispersing the abovementioned conductive particles without causing aggregation. Examples of the dispersion medium include water as well as methanol, ethanol, propanol, butanol, and other alcohols; n-heptane, n-octane, decane, dodecane, tetradecane, toluene, xylene, cymene, durene, indene, dipentene, tetrahydronaphthalene, dekahydronaphthalene, cyclohexylbenzene, and other hydrocarbon-based compounds; ethylene glycol dimethylether, ethylene glycol diethylether, ethylene glycol methylethylether, diethylene glycol dimethylether, diethylene glycol diethylether, diethylene glycol methylethylether, 1,2-dimethoxyethane, bis(2-methoxyethyl)ether, p-dioxane, and other ether-based compounds; and propylene carbonate, y-butyrolactone, N-methyl-2-pyrrolidone, dimethyl formamide, dimethyl sulfoxide, cyclohexanone, and other polar compounds. Among these, water, alcohols, hydrocarbon-based compounds, and ether-based compounds are preferred in terms of the ability to disperse the particles, the stability of the liquid dispersion, and ease of application to the droplet discharge method, and water and hydrocarbon-based compounds can be cited as more preferred dispersion mediums.

The surface tension of the liquid dispersion of the abovementioned conductive particles is preferably within the range of 0.02 N/m and 0.07 N/m. When the liquid material is discharged by the droplet discharge method, the wetting properties of the liquid material with respect to the nozzle face increase when the surface tension is less than 0.02 N/m, and flying deflection therefore occurs easily. Since the shape of the meniscus at the distal ends of the nozzles 52 is unstable when the surface tension exceeds 0.07 N/m, the discharged amount and the discharge timing become difficult to control. A trace amount of a surface tension adjusting agent based on fluorine or silicone, or a nonionic surface tension adjusting agent or the like may be added to the dispersion liquid in a range that does not significantly reduce the angle of contact with the substrate W in order to adjust the surface tension. A nonionic surface tension adjusting agent serves to enhance the wetting properties of the liquid material with the substrate W, improve the film leveling properties, and prevent the occurrence of minute surface irregularities and the like on the film. The surface tension adjusting agent may include alcohols, ethers, esters, ketones, and other organic compounds as needed.

The viscosity of the abovementioned liquid material is preferably 1 mPa·s to 50 mpa·s. When the liquid material is discharged in the form of droplets D by the droplet discharge method, the parts on the periphery of the nozzles 52 are easily contaminated by the flow of the liquid material when the viscosity is less than 1 mPa·s. The frequency of obstruction of the nozzle holes increases, and a smooth discharge of droplets is difficult when the viscosity is greater than 50 mPa·s. The process then proceeds to step S4.

Step S4 of FIG. 7 is the drying/baking step. In step S4, the discharged liquid material is cured by drying and baking to form the wiring 301, 303. Drying and baking may be performed according to a batch system in which the substrate W is placed in a drying oven and dried/baked at a prescribed temperature or an in-line system in which the substrate W is passed through a drying oven. The heat source may be a heater, an infrared lamp, or the like. The process then proceeds to step S5.

Step S5 of FIG. 7 is the step for discharging the liquid material that includes an insulation material. In step S5, the liquid material that includes a insulation material is filled into the droplet discharge heads 50, and the control computer 10 controls the primary scanning stage 2a and the secondary scanning stage 3a to cause the head unit 9 and the substrate W to move relative to each other, and drives the droplet discharge heads 50 mounted in the head unit 9. In this case, the bit map data for arranging the liquid material in the insulation film formation region 306 (see FIG. 6) are created based on CAD data of the insulation film formation region 306 and stored in the memory of the control computer 10. The liquid material is discharged based on the bit map data. Since the insulation film 307 need not be formed with high positional accuracy, there is no need to correct for flying deflection in this case.

An epoxy resin, a urethane resin, or other polymer material having insulation properties, for example, may be used as the insulation material. Examples of the solvent include hydrocarbon-based solvents that are capable of dissolving the above-mentioned material. The physical properties of the liquid material are adjusted according to the droplet discharge method in the same manner as the liquid material that includes the conductive material. The process then proceeds to step S6.

Step S6 of FIG. 7 is the drying/film formation step. In step S6, the discharged liquid material is cured by drying to form the insulation film 307. A photosensitive resin material may also be used as the insulation material. In this case, the discharged liquid material is cured by irradiation with ultraviolet rays or the like.

The liquid material discharge method based on the corrected bit map data in which the flying deflection is corrected in the method for manufacturing such a wiring substrate 300 is not limited to a method in which the discharge timing is varied by selecting a latch signal (LAT). Any of the drive signals W2, W3 having different discharge rates for nozzles 52 in which flying deflection occurs may be selected to discharge the liquid material at a different discharge rate. According to this configuration, not only is it possible to reduce misalignment of the landing positions in the primary scanning direction, but misalignment of the landing positions in the secondary scanning direction (Y-axis direction) can also be reduced.

The checking step (step S1) and the arrangement pattern generation step (step S2) were performed for each discharging and drawing on a single substrate W, but may also be performed before and during the discharge and drawing operations for each of a plurality of substrate W.

The effects of the first embodiment are as described below.

(1) In the method for manufacturing a wiring substrate 300 that uses the liquid material discharge method of the first embodiment, the discharge timing is varied for discharge based on corrected bit map data that are corrected with respect to a nozzle 52 in which flying deflection occurs. Accordingly, the effects of flying deflection can be reduced, the liquid material can be arranged with good positional accuracy, and a wiring substrate 300 having consistently shaped wiring 301, 303 can be manufactured.

(2) In the method for manufacturing a wiring substrate 300 that uses the liquid material discharge method of the first embodiment, the landing position information of the droplets D discharged from the plurality of nozzles 52 is acquired for the forward movement and the reverse movement in the same manner as in primary scanning in the checking step of step S1. Consequently, more accurate landing position information can be acquired, and the droplets D can be arranged with higher positional accuracy on the substrate W. Specifically, it is possible to manufacture a wiring substrate 300 that has extremely fine wiring 301, 303.

### SECOND EMBODIMENT

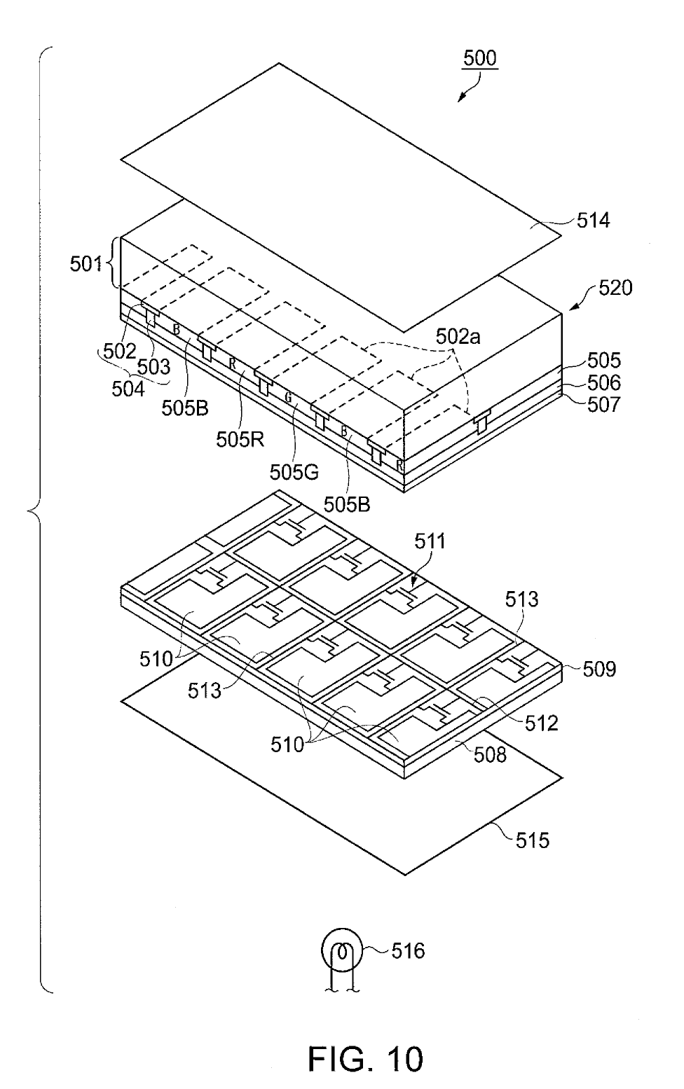

Referring now to FIGS. 10 to 12, a color filter manufacturing method in accordance with a second embodiment will now be explained. In view of the similarity between the first and second embodiments, the parts of the second embodiment that are identical to the parts of the first embodiment will be given the same reference numerals as the parts of the first embodiment. Moreover, the descriptions of the parts of the second embodiment that are identical to the parts of the first embodiment may be omitted for the sake of brevity.

The color filter manufacturing method will next be described as another embodiment in which the liquid material discharge method of the first embodiment is applied.

The liquid crystal display device as an electro-optical device having a color filter will first be briefly described. FIG. 10 is a schematic perspective view showing the structure of the liquid crystal display device. As shown in FIG. 10, the liquid crystal display device 500 of the present embodiment is provided with a TFT (Thin Film Transistor) transmissive liquid crystal display panel 520 and an illumination device 516 for illuminating the liquid crystal display panel 520. The liquid crystal display panel 520 is provided with an opposing substrate 501 having color layers 505 as color filters; an element substrate 508 having TFT elements 511 in which one of three terminals is connected to a pixel electrode 510; and liquid crystals (not shown) that are held between both substrates 501, 508. An upper polarizer 514 and a lower polarizer 515 for polarizing the transmitted light are provided to the surfaces of both substrates 501, 508 that form the outside of the liquid crystal display panel 520.

The opposing substrate 501 is composed of transparent glass or another material, and a plurality of types (three colors: RGB) of color layers 505R, 505G, 505B is formed in a plurality of color regions that is partitioned into a matrix by partition wall parts 504 on the surfaces that sandwich the liquid crystal. The partition wall parts 504 are composed of lower-layer banks 502 referred to as a black matrix that are composed of Cr or another metal or oxide thereof that has light-blocking properties, and upper-layer banks 503 composed of an organic compound that are formed on (downward in the drawing) the lower-layer banks 502. The opposing substrate 501 is provided with an overcoat layer (OC layer) 506 as a planarizing layer for covering the color layers 505R, 505G, 505B that are partitioned by the partition wall parts 504; and an opposing electrode 507 composed of ITO (Indium Tin Oxide) or another transparent conductive film that is formed so as to cover the OC layer 506. The color layers 505R, 505G, 505B are manufactured using the color filter manufacturing method described hereinafter.

The element substrate 508 is also composed of a glass or other transparent material, and has pixel electrodes 510 formed in a matrix via an insulation film 509 on the side on which the liquid crystals are sandwiched, and a plurality of TFT elements 511 formed so as to correspond to the pixel electrodes 510. Of the three terminals of the TFT elements 511, the other two terminals that are not connected to the pixel electrodes 510 are connected to scanning lines 512 and data lines 513 that are arranged in a lattice so as to surround and insulate the pixel electrodes 510 from each other.

The illumination device 516 may be any illumination device that uses a white LED, EL, cold cathode tube, or the like as a light source, and that has a structure provided with a light-guide plate, a diffusion plate, a reflection plate, or the like that is capable of emitting the light from the light source to the liquid crystal display panel 520.

The liquid crystal display panel 520 is not limited to having TFT elements as the active elements, and may have a TFD (Thin Film Diode) element. When the liquid crystal display panel 520 is provided with a color filter on at least one of the substrates, the liquid crystal display panel 520 may be a passive liquid crystal display device in which the electrodes constituting the pixels are arranged so as to intersect each other. The upper and lower polarizers 514, 515 may also have phase difference films or other optically functional films that are used for such purposes as improving the viewing angle dependency.

### Color Filter Manufacturing Method

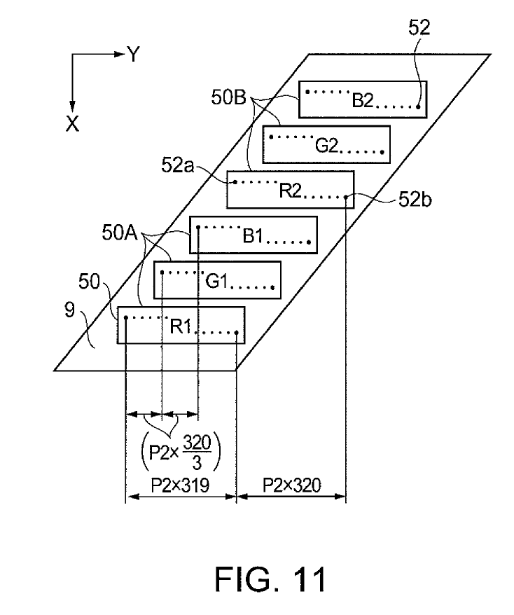

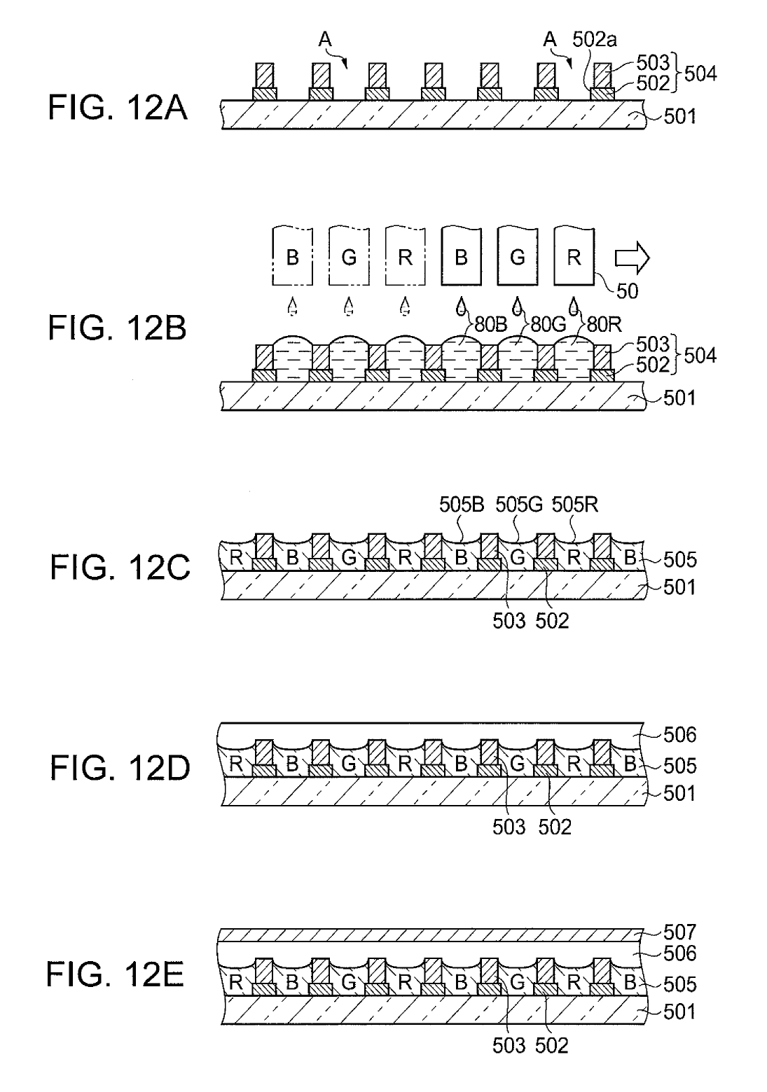

The color filter manufacturing method of the present embodiment will next be described based on FIGS. 11 and 12. FIG. 11 is a schematic plan view showing the arrangement of the droplet discharge heads with respect to the head unit, and FIGS. 12A through 12E are schematic sectional views showing the color filter manufacturing method.

The arrangement of the droplet discharge heads 50 in the head unit 9 in a manner suitable for manufacturing a color filter having color layers in multiple colors will first be described.

As shown in FIG. 1, the six droplet discharge heads 50 for discharging three types (RGB) of the liquid material that includes a color layer forming material are mounted in alignment with the Y-axis direction (secondary scanning direction). The droplet discharge heads 50 are also mounted in RGB sequence in the X-axis direction (primary scanning direction). The positions of the end parts of the nozzle rows 52a, 52b for discharging different types of the liquid material are offset from each other. In the head unit 9, two head groups 50A, 50B in which three droplet discharge heads 50 that discharge different types of the liquid material are in a group are mounted along the X-axis direction. The amount of offset in this case is the value obtained by dividing the sum of the entire length (for 320 effective nozzles) of nozzle row 52a and nozzle row 52b and the single nozzle pitch P2 by the number of types of the discharged liquid material. Specifically, ((P2×319)+P2)/3=(P2×320)/3. According to this configuration, when viewed from the X-axis direction (primary scanning direction), the nozzles 52 of head R1 and head R2 of the droplet discharge heads 50 that discharge the same type of liquid material are arranged in a state in which 320×2=640 nozzles are continuous at the nozzle pitch P2. The same applies for the droplet discharge heads 50 that discharge the same type of liquid material in heads G1 and G2, and heads B1 and B2. In head group 50A, the end parts of the nozzle rows 52a of heads R1, G1, and B1 that discharge different types of the liquid material are offset from each other by (P2×320)/3, whereby the end parts are positioned farthest away from each other. The same also applies in the other head group 50B.

The configuration of the head unit 9 described above makes it possible to discharge three different types of the liquid material in a drawing width in which the drawing width of a single droplet discharge head 50 for discharging the same type of the liquid material is continuous in the Y-axis direction (secondary scanning direction) in a single primary scan using the plurality of droplet discharge heads 50 mounted in the head unit 9.

The color filter manufacturing method of the present embodiment is provided with a step for forming partition wall parts 504 on the surface of the opposing substrate 501, and a step for treating the surfaces of the color regions that are partitioned by the partition wall parts 504. The manufacturing method is also provided with a drawing step for discharging and drawing using droplets of three types (three colors) of the liquid material that includes a color layer forming material in the surface-treated color regions using the droplet discharge device 1, and a film formation step for drying the drawn liquid material to form color layers 505. The manufacturing method is furthermore provided with a step for forming the OC layer 506 so as to cover the partition wall parts 504 and the color layers 505, and a step for forming the transparent opposing electrode 507 that is composed of ITO so as to cover the OC layer 506. The drawing step includes the checking step, the arrangement pattern generation step, and the discharge step in the liquid material discharge method of the first embodiment.

In the step for forming the partition wall parts 504, the lower-layer banks 502 as the black matrix are first formed on the opposing substrate 501, as shown in FIG. 12A. The material used to form the lower-layer banks 502 may be Cr, Ni, Al, or another non-transparent metal, or an oxide or other compound of these metals, for example. The lower-layer banks 502 are formed by a method in which a film composed of the abovementioned material is formed on the opposing substrate 501 using vapor deposition or sputtering. The film thickness may be set according to a material having an appointed film thickness that allows light-blocking properties to be maintained. For example, a thickness of 100 to 200 nm is preferred when the material is Cr. The film in areas other than the portions that correspond to the open parts 502a (see FIG. 10) is covered by a resist according to a photolithography method, and the film is etched using oxygen or another etching solution that corresponds to the abovementioned material. The lower-layer banks 502 having open parts 502a are thereby formed.

The upper-layer banks 503 are then formed on the lower-layer banks 502. An acrylic-based photosensitive resin material is used as the material for forming the upper-layer banks 503. The photosensitive resin material preferably has light-blocking properties. In an example of the method for forming the upper-layer banks 503, a photosensitive resin material is applied by roll coating or spin coating to the surface of the opposing substrate 501 on which the lower-layer banks 502 are formed, and the photosensitive resin material is dried to from a photosensitive resin layer having a thickness of about 2 μm. A mask provided with open parts that are sized according to the color regions A is then positioned opposite the opposing substrate 501 in a prescribed position, and exposure/development are performed to form the upper-layer banks 503. The partition wall parts 504 for partitioning the plurality of color regions A in a matrix are thereby formed on the opposing substrate 501. The process then proceeds to the surface treatment step.

In the surface treatment step, plasma treatment using O₂ as the treatment gas, and plasma treatment using a fluorine-based gas as the treatment gas are performed. Specifically, the color regions A are subjected to a lyophilizing treatment, and the surfaces of the upper-layer banks 503 (including the wall surfaces) composed of the photosensitive resin are then subjected to a fluid repellant treatment. The process then proceeds to the checking step.

In the checking step, the landing position information of the droplets discharged from all of the droplet discharge heads 50 is acquired. In this case, the plurality of droplet discharge heads 50 is arranged in the head unit 9 so as to correspond to the three types (three colors) of the liquid material. Consequently, the control computer 10 controls the driving of the primary scanning stage 2a and the droplet discharge heads 50 so that droplets of the same color of the liquid material land in a straight line in the Y-axis direction of the recording paper. The recording operation is performed for the forward movement and the reverse movement of primary scanning in the same manner as in the first embodiment. As previously mentioned, the landing state of the droplets is imaged for each color and each nozzle row using a camera provided with a CCD or other imaging element. The landing position information of the plurality of nozzles 52 of the droplet discharge heads 50 can thereby be acquired for each color and each nozzle row.

In the arrangement pattern generation step, bit map data in which three types of the liquid material are arranged in a striped formation in the plurality of color regions A partitioned on the opposing substrate 501 are created and stored in advance in the memory of the control computer 10. In other words, the arrangement of the color regions A and the arrangement of the nozzles 52 in the primary scanning, are reflected in the bit map data. In the abovementioned checking step, corrected bit map data are generated based on the landing position information of the nozzles 52 that is acquired for each color and each nozzle row. In this case, since the color regions A are partitioned by the partition wall parts 504, the original bit map data are preferably corrected so that at least a portion of the droplets of the liquid material do not land on the partition wall parts 504, or so that the droplets of the liquid material do not land in the vicinity of the partition wall parts 504. The necessary amount of droplets can thereby be landed without occurring outside the color regions A even when there is a nozzle 52 in which flying deflection occurs. It is also possible to reduce the occurrence of color mixing due to flying deflection of droplets between color regions A in which different colors of the liquid material are arranged.

In the discharge step, droplets of the liquid material 80R, 80G, 80B in the corresponding colors for the surface-treated color regions A are discharged and drawn as shown in FIG. 12B. The liquid material 80R includes R (red) color-filter-forming material, the liquid material 80G includes G (green) color-filter-forming material, and the liquid material 80B includes B (blue) color-filter-forming material. The liquid material 80R, 80G, 80B is filled into the droplet discharge heads 50 and landed as droplets in the color regions A using the droplet discharge device 1. At this time, the droplets are discharged at a different timing for nozzles 52 in which flying deflection occurs based on the abovementioned corrected bit map data. Alternatively, discharge is performed at a different rate. The necessary amounts of the liquid material 80R, 80G 80B are provided according to the surface area of the color regions A, the liquid material spreads in color regions A and rises due to surface tension. Using the droplet discharge device 1 makes it possible to discharge and draw using three different types of the liquid material 80R, 80G, 80B at the same time.

In the subsequent film formation step, the discharged liquid material 80R, 80G, 80B is dried at once to remove the solvent component, and films of the color layers 505R, 505G, 505B are formed, as shown in FIG. 12C. Vacuum drying or another method that is capable of uniformly drying the solvent components is preferred as the drying method. The process then proceeds to the OC layer formation step.

In the OC layer formation step, the OC layer 506 is formed so as to cover the color layers 505 and the upper-layer banks 503, as shown in FIG. 12D. A transparent acrylic-based resin material may be used as the OC layer 506. Formation methods include spin coating, offset printing, and other methods. The OC layer 506 is provided to mitigate irregularities in the surface of the opposing substrate 501 on which the color layers 505 are formed, and to flatten the opposing electrode 507 that is subsequently formed as a film on the surface of the opposing substrate 501. A thin film of SiO₂ or the like may also be formed on the OC layer 506 to maintain adhesion with the opposing electrode 507. The process then proceeds to the transparent electrode formation step.

In the transparent electrode formation step, a film of ITO or another transparent electrode material is formed in a vacuum using sputtering or vapor deposition, and the opposing electrode 507 is formed on the entire surface so as to cover the OC layer 506, as shown in FIG. 12E.

The color layers 505 of the opposing substrate 501 formed in this manner have a substantially uniform thickness in the color regions A, and have a reduced occurrence of irregular discharge or color mixing due to flying deflection of the droplets. The opposing substrate 501 and the element substrate 508 that has the pixel electrodes 510 and the TFT elements 511 are bonded in the prescribed position using an adhesive, and liquid crystals are filled in between the substrates 501, 508, whereby a liquid crystal display device 500 is created that has attractive display quality and minimal color irregularity caused by irregular discharge or color mixing.

The effects of the second embodiment are as described below.

(1) In the color filter manufacturing method according to The second embodiment, based on the corrected bit map data, droplets of the three types (three colors) of the liquid material are discharged in the color regions A partitioned by the partition wall parts 504 at a different discharge timing or a different discharge rate for a nozzle 52 in which flying deflection occurs in the discharge step. Accordingly, it is possible to manufacture a color filter in which the color layers 505 have a substantially uniform thickness in the color regions A, and have a reduced occurrence of irregular discharge or color mixing due to flying deflection of the droplets.

(2) A liquid crystal display device 500 that has attractive display quality and minimal color irregularity and other defects can be provided by manufacturing the liquid crystal display device 500 using an opposing substrate 501 that is manufactured using the color filter manufacturing method according to The second embodiment.

### THIRD EMBODIMENT

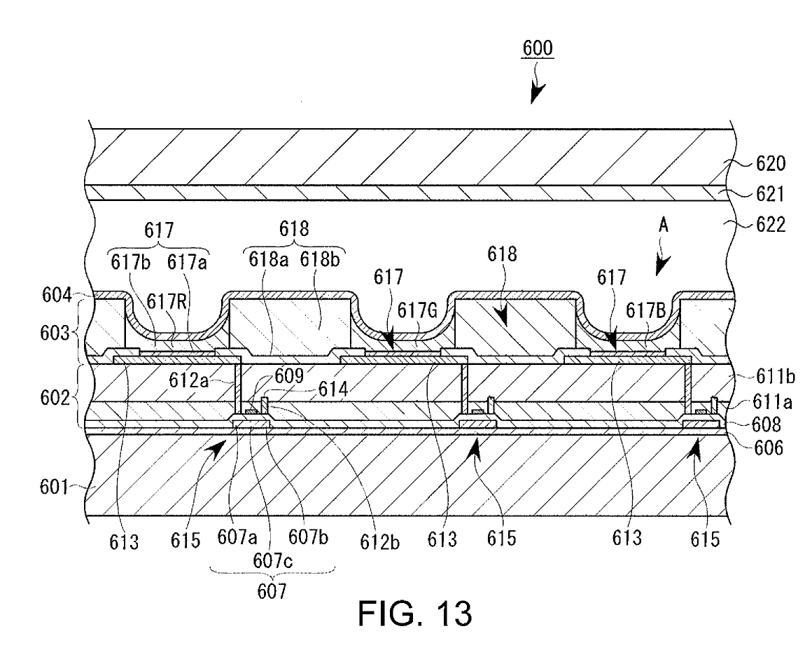

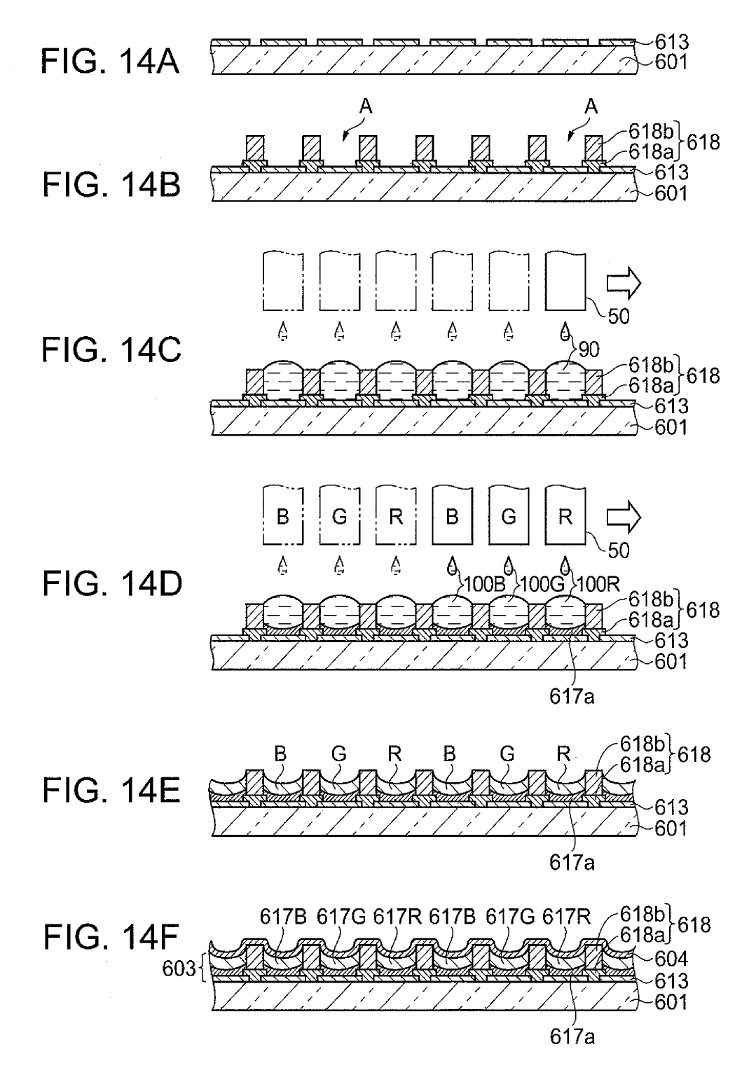

Referring now to FIGS. 13 and 14, an organic EL element manufacturing method in accordance with a third embodiment will now be explained. In view of the similarity between the first and third embodiments, the parts of the third embodiment that are identical to the parts of the first embodiment will be given the same reference numerals as the parts of the first embodiment. Moreover, the descriptions of the parts of the third embodiment that are identical to the parts of the first embodiment may be omitted for the sake of brevity.

The organic EL element manufacturing method will next be described as another embodiment in which the liquid material discharge method of the first embodiment is applied.

The organic EL display device having the organic EL element will first be briefly described.

FIG. 13 is a schematic sectional view showing the relevant parts of the structure of the organic EL display device. As shown in FIG. 13, the organic EL display device 600 is provided with an element substrate 601 that has a luminescent element part 603 as the organic EL element; and a sealing substrate 620 that is sealed at a distance from the element substrate 601 and a space 622. The element substrate 601 is also provided with a circuit element part 602 on the element substrate 601, and the luminescent element part 603 is formed over the circuit element part 602 and driven by the circuit element part 602. Three colors of luminescent layers 617R, 617G, 617B as organic EL luminescent layers are formed in luminescent layer formation regions A in a striped pattern in the luminescent element part 603. In the element substrate 601, three luminescent layer formation regions A that correspond to three colors of color layers 617R, 617G, 617B form a single set of picture elements, and the picture elements are arranged in a matrix on the circuit element part 602 of the element substrate 601. In the organic EL display device 600, the light emitted from the luminescent element part 603 is emitted toward the element substrate 601.

The sealing substrate 620 is composed of glass or metal, and is bonded to the element substrate 601 via a sealing resin. A getter agent 621 is affixed to the sealed inside surface. The getter agent 621 absorbs water or oxygen that enters the space 622 between the element substrate 601 and the sealing substrate 620 and prevents the luminescent element part 603 from being degraded by the contaminating water or oxygen. The getter agent 621 may also be omitted.

The element substrate 601 has a plurality of luminescent layer formation regions A on the circuit element part 602, and is provided with partition wall parts 618 for partitioning the plurality of luminescent layer formation regions A; electrodes 613 formed in the plurality of luminescent layer formation regions A; and positive hole implantation/transport layers 617a that are layered on the electrodes 613. The luminescent element part 603 is also provided that has luminescent layers 617R, 617G, 617B formed by applying the three types of the liquid material that include a luminescent-layer-forming material in the plurality of luminescent layer formation regions A. The partition wall parts 618 are composed of lower-layer banks 618a, and upper-layer banks 618b that essentially partition the luminescent layer formation regions A, wherein the lower-layer banks 618a are provided so as to protrude into the luminescent layer formation regions A, and the electrodes 613 and the luminescent layers 617R, 617G, 617B are formed by SiO₂ or another inorganic insulation material so as to prevent direct contact and electrical short circuiting with each other.

The element substrate 601 is composed of glass or another transparent substrate, for example, a base protective film 606 composed of a silicon oxide film is formed on the element substrate 601, and islands of semiconductor films 607 composed of polycrystalline silicon are formed on the base protective film 606. A source region 607a and a drain region 607b are formed by high-concentration P ion implantation in the semiconductor films 607. The portion into which P is not implanted is the channel region 607c. A transparent gate insulation film 608 for covering the base protective film 606 and the semiconductor films 607 is also formed, gate electrodes 609 composed of Al, Mo, Ta, Ti, W, or the like are formed on the gate insulation film 608, and a transparent first interlayer insulation film 611a and second interlayer insulation film 611b are formed on the gate electrodes 609 and the gate insulation film 608. The gate electrodes 609 are provided in positions that correspond to the channel regions 607c of the semiconductor films 607. Contact holes 612a, 612b that are connected to the source regions 607a and the drain regions 607b, respectively, of the semiconductor films 607 are also formed so as to penetrate through the first interlayer insulation film 611a and the second interlayer insulation film 611b. Transparent electrodes 613 composed of ITO (Indium Tin Oxide) are patterned in a prescribed shape and arranged (electrode formation step) on the second interlayer insulation film 611b, and the contact holes 612a are connected to the electrodes 613. The other contact holes 612b are connected to power supply lines 614. Thin film transistors 615 for driving that are connected to the electrodes 613 are formed in the circuit element part 602 in this manner. Retention capacitors and thin film transistors for switching are also formed in the circuit element part 602, but these components are not shown in FIG. 13.

The luminescent element part 603 is provided with the electrodes 613 as positive electrodes, the positive hole implantation/transport layers 617a and the luminescent layers 617R, 617G, 617B (referred to generically as luminescent layers 617b) that are layered in sequence on the electrodes 613, and the negative electrode 604 that is layered so as to cover the upper-layer banks 618b and the luminescent layers 617b. The functional layer 617 in which luminescence is induced is composed of the positive hole implantation/transport layers 617a and the luminescent layers 617b. Using a transparent material to form the negative electrode 604, the sealing substrate 620, and the getter agent 621 enables the light generated from the direction of the sealing substrate 620 to be emitted.

The organic EL display device 600 has scanning lines (not shown) connected to the gate electrodes 609, and signal lines (not shown) connected to the source regions 607a, and when the thin film transistors (not shown) for switching are turned on by the scanning signal transmitted to the scanning lines, the potential of the signal lines at that time is maintained by the retention capacitors, and the on/off state of the thin film transistors 615 for driving is determined according to the state of the retention capacitors. Electric current flows from the power supply lines 614 to the electrodes 613 via the channel regions 607c of the thin film transistors 615 for driving, and the electric current then flows to the negative electrode 604 via the positive hole implantation/transport layers 617a and the luminescent layers 617b. The luminescent layers 617b emit light according to the amount of flowing current. The organic EL display device 600 can display the desired characters or image through the light emission mechanism of the luminescent element part 603 thus configured. Since an image is formed by the luminescent layers 617b using the liquid material discharge method that uses the droplet discharge device 1, high image quality is obtained in which there is minimal uneven light emission, uneven luminance, or other display defects caused by uneven discharge during drawing.

### Organic El Element Manufacturing Method

The method for manufacturing a luminescent element part as the organic EL element of the present embodiment will next be described based on FIG. 14. FIGS. 14A through 14F are schematic sectional views showing the method for manufacturing a luminescent element part. The circuit element part 602 formed on the element substrate 601 is not shown in FIGS. 14A through 14F.

The method for manufacturing the luminescent element part 603 of the present embodiment is provided with a step for forming the electrodes 613 in positions that correspond to the plurality of luminescent layer formation regions A of the element substrate 601, and a barrier part formation step for forming the lower-layer banks 618a so as to partially overlap on the electrodes 613, and forming the upper-layer banks 618b on the lower-layer banks 618a so as to essentially partition the luminescent layer formation regions A. The manufacturing method is also provided with a step for performing surface treatment of the luminescent layer formation regions A that are partitioned by the upper-layer banks 618b, a step for applying the liquid material that includes a positive hole implantation/transport layer forming material in the surface-treated luminescent layer formation regions A to draw the positive hole implantation/transport layers 617a by discharging, and a step for drying the discharged liquid material to form the positive hole implantation/transport layers 617a. The manufacturing method is also provided with a step for performing surface treatment of the luminescent layer formation regions A in which the positive hole implantation/transport layers 617a are formed, a drawing step for discharging and drawing three types of the liquid material that includes the luminescent layer forming material in the surface-treated luminescent layer formation regions A, and a step for drying the discharged three types of the liquid material to form the luminescent layers 617b. The manufacturing method is furthermore provided with a step for forming the negative electrode 604 so as to cover the upper-layer banks 618b and the luminescent layers 617b. The three types of the liquid material are applied to the luminescent layer formation regions A using the same liquid material discharge method as was used in the color filter manufacturing method of the second embodiment. The arrangement of the droplet discharge heads 50 with respect to the head unit 9 shown in FIG. 11 is thereby applied.

In the electrode (positive electrode) formation step, the electrodes 613 are formed in positions that correspond to the luminescent layer formation regions A of the element substrate 601 on which the circuit element part 602 is already formed, as shown in FIG. 14A. In an example of the formation method, a transparent electrode film is formed on the surface of the element substrate 601 by sputtering or vapor deposition in a vacuum using ITO or another transparent electrode material. A photolithography method is then used to leave only the necessary portion, and the electrodes 613 may be formed by etching. The element substrate 601 is covered in advance by a photoresist, and exposure/development are performed so as to open the regions for forming the electrodes 613. A transparent electrode film of ITO or the like may then be formed in the open parts, and the remaining photoresist may be removed. The process then proceeds to the bank formation step.

In the barrier part formation step, the lower-layer banks 618a are formed so as to cover portions of the plurality of electrodes 613 of the element substrate 601, as shown in FIG. 14B. The material used to form the lower-layer banks 618a is SiO₂ (silicon dioxide), which is an inorganic material having insulation properties. In an example of the method for forming the lower-layer banks 618a, the surfaces of the electrodes 613 are masked using a resist or the like so as to correspond to the subsequently formed luminescent layers 617b. The masked element substrate 601 is then placed in a vacuum device, and the lower-layer banks 618a are formed by sputtering or vacuum deposition using SiO₂ as the target or source material. The resist or other mask is subsequently peeled off. Since the lower-layer banks 618a are formed by SiO₂, adequate transparency is obtained when the film thickness thereof is 200 nm or less, and light emission is not inhibited even when the positive hole implantation/transport layers 617a and the luminescent layers 617b are subsequently layered.

The upper-layer banks 618b are then formed on the lower-layer banks 618a so as to essentially partition the luminescent layer formation regions A. The material used to form the upper-layer banks 618b is preferably a material that is durable with respect to the solvent of the three types of liquid material 100R, 100G, 100B that include the luminescent layer forming material described hereinafter, and a material that can be given a fluid-repellent treatment through the use of a plasma treatment using a fluorine-based gas as the treatment gas is preferred, e.g., an organic material such as an acrylic resin, an epoxy resin, a photosensitive polyimide, or the like. In an example of the method for forming the upper-layer banks 618b, the abovementioned photosensitive organic material is applied by roll coating or spin coating to the surface of the element substrate 601 on which the lower-layer banks 618a are formed, and the coating is dried to form a photosensitive resin layer having a thickness of about 2 μm. A mask provided with open parts whose size corresponds to the luminescent layer formation regions A is then placed against the element substrate 601 in a prescribed position, and exposure/development is performed, whereby the upper-layer banks 618b are formed. The partition wall parts 618 having lower-layer banks 618a and upper-layer banks 618b are thereby formed. The process then proceeds to the surface treatment step.

In the step for treating the surfaces of the luminescent layer formation regions A, the surface of the element substrate 601 on which the partition wall parts 618 are formed is first plasma treated using O₂ gas as the treatment gas. The surfaces of the electrodes 613, the protruding parts of the lower-layer banks 618a, and the surfaces (including the wall surfaces) of the upper-layer banks 618b are thereby activated and lyophilized. Plasma treatment is then performed using CF₄ or another fluorine-based gas as the treatment gas. The fluorine-based gas is thereby reacted with only the surfaces of the upper-layer banks 618b that are composed of the photosensitive resin as an organic material, and the surfaces are rendered fluid repellent. The process then proceeds to the positive hole implantation/transport layer formation step.

In the positive hole implantation/transport layer formation step, a liquid material 90 that includes a positive hole implantation/transport layer forming material is applied in the positive hole implantation/transport layer formation regions A, as shown in FIG. 14C. The method for applying the liquid material 90 uses the droplet discharge device 1 provided with the head unit 9 shown in FIG. 11. The liquid material 90 discharged from the droplet discharge heads 50 lands as droplets on the electrodes 613 of the element substrate 601 and spreads. The necessary amount of the liquid material 90 according to the surface area of the positive hole implantation/transport layer formation regions A is discharged as droplets, and the liquid material 90 rises due to surface tension. The process then proceeds to the drying/film-formation step.

In the drying/film-formation step, the solvent component of the liquid material 90 is dried and removed by heating the element substrate 601 by a lamp annealing method or other method, for example, and the positive hole implantation/transport layers 617a are formed in the regions partitioned by the lower-layer banks 618a of the electrodes 613. In the present embodiment, PEDOT (Polyethylene Dioxy Thiophene) is used as the positive hole implantation/transport layer forming material. Positive hole implantation/transport layers 617a composed of the same material are formed in the luminescent layer formation regions A in this case, but the material for forming the positive hole implantation/transport layers 617a may also be varied for each luminescent layer formation region A according to the subsequently formed luminescent layers 617b. The process then proceeds to the surface treatment step.

In the surface treatment step, when the positive hole implantation/transport layers 617a are formed using the abovementioned positive hole implantation/transport layer forming material, since the surfaces thereof repel the three types of liquid material 100R, 100G, 100B, a surface treatment is again performed so that at least the areas within the luminescent layer formation regions A are lyophilic. The surface treatment is performed by a method in which the solvent used in the three types of liquid material 100R, 100G, 100B is applied and dried. A spraying method, a spin coating method, or other method may be used to apply the solvent. The process then proceeds to the luminescent layer drawing step.

In the luminescent layer drawing step, the droplet discharge device 1 is used to apply the three types of liquid material 100R, 100G, 100B including the luminescent layer forming material from the plurality of droplet discharge heads 50 to the plurality of luminescent layer formation regions A, as shown in FIG. 14D. The liquid material 100R includes a material for forming the luminescent layers 617R (red), the liquid material 100G includes a material for forming the luminescent layers 617G (green), and the liquid material 100B includes a material for forming the luminescent layers 617B (blue). The liquid bodies 100R, 100G, 100B thus landed spread out in the luminescent layer formation regions A and rise to form shapes that have an arcuate profile. The method for applying the liquid bodies 100R, 100G, 100B is the same as in the color filter manufacturing method of the second embodiment, and includes a checking step for acquiring the droplet landing position information, an arrangement pattern generation step for generating corrected bit map data in which the bit map data based on the design data (CAD data) of the luminescent layer formation regions A are corrected based on the landing position information, and a discharge step for discharging the droplets at a different discharge timing or discharge rate based on the corrected bit map data for a nozzle 52 in which flying deflection occurs. In the discharge step, the corrected bit map data are used to control the discharge so that at least a portion of the droplets discharged from the nozzle 52 in which flying deflection occurs do not land on the partition wall parts 618, or do not land in the vicinity of the partition wall parts 618. The process then proceeds to the drying/film-formation step.

In the drying/film-formation step, the solvent component of the discharged and drawn liquid bodies 100R, 100G, 100B is dried and removed, and films are formed so that the luminescent layers 617R, 617G, 617B are layered on the positive hole implantation/transport layers 617a of the luminescent layer formation regions A, as shown in FIG. 14E. A vacuum drying method that enables the solvent to be evaporated at a substantially constant rate is preferred as the method for drying the element substrate 601 on which the liquid bodies 100R, 100G, 100B are discharged and drawn. The process then proceeds to the negative electrode formation step.

In the negative electrode formation step, the negative electrode 604 is formed so as to cover the upper-layer banks 618b and the luminescent layers 617R, 617G, 617B of the element substrate 601, as shown in FIG. 14F. A combination of Ca, Ba, Al, or another metal and LiF or another fluoride is preferably used as the material for forming the negative electrode 604. It is particularly preferred that a film of Ca, Ba, or LiF having a small work function be formed on the side towards the luminescent layers 617R, 617G, 617B, and that a film of Al or the like having a large work function be formed on the side facing away from the luminescent layers. A protective layer of SiO₂, SiN, or the like may also be layered on the negative electrode 604. The negative electrode 604 can thereby be prevented from oxidizing. Methods used to form the negative electrode 604 include vapor deposition, sputtering, CVD, and other methods. Vapor deposition is particularly preferred, since this method makes it possible to prevent the luminescent layers 617R, 617G, 617B from being damaged by heat.

The element substrate 601 completed in this manner has luminescent layers 617R, 617G, 617B having a substantially constant thickness after drying and film formation, and in which there is minimal irregular discharge due to flying deflection during discharge and drawing.

The effects of the third embodiment are as described below.

(1) In the method for manufacturing the luminescent element part 603 according to The third embodiment, in the drawing step for the luminescent layers 617b, droplets of the liquid bodies 100R, 100G, 100B are discharged and drawn in the luminescent layer formation regions A of the element substrate 601 based on the corrected bit map data. Since the droplets are discharged at a different discharge timing or a different discharge rate for a nozzle 52 in which flying deflection occurs, the droplets are arranged in the appropriate positions of the luminescent layer formation regions A. Consequently, luminescent layers 617R, 617G, 617B are obtained that have a substantially constant thickness after drying and film formation, and minimal irregular discharge due to flying deflection during discharge and drawing.

(2) When the organic EL display device 600 is manufactured using the element substrate 601 that is manufactured using the method for manufacturing the luminescent element part 603 according to The third embodiment, the thickness of the luminescent layers 617R, 617G, 617B is substantially constant, and the resistance of each luminescent layer 617R, 617G, 617B is therefore substantially constant. Uneven luminescence, uneven luminance, and other defects due to unequal resistance in each luminescent layer 617R, 617G, 617B is thereby reduced when the drive voltage is applied by the circuit element part 602 to the luminescent element part 603 to generate light. Specifically, an organic EL display device 600 can be provided that has attractive display quality and a minimal occurrence of uneven luminescence, uneven luminance, and other defects due to uneven discharge caused by flying deflection.

Embodiments of the present invention were described above, but various modifications may be added to the embodiments described above in ranges that do not depart from the intended scope of the present invention. Examples of modifications other than the abovementioned embodiments are described below.

### MODIFICATION EXAMPLE 1

In the liquid material discharge method of the first embodiment, discharge control of a nozzle 52 in which flying deflection occurs that is based on the landing position information of the plurality of nozzles 52 is not limited to a method in which the original bit map data are corrected. For example, a circuit for advancing or delaying the timing at which the latch signal is generated may be incorporated in the control circuit board 40, and control may be performed so that advancing or delaying is selected.

### MODIFICATION EXAMPLE 2

In the liquid material discharge method of the first embodiment, the checking step (step S1) for acquiring the landing position information is not limited as such. For example, a procedure may be repeated in which a nozzle 52 in which flying deflection occurs is specified based on the acquired landing position information, a drive signal having a different discharge timing or discharge rate is applied to the piezoelectric element (oscillator) 59 that corresponds to the nozzle 52, and the landing position information is re-acquired. An assessment can thereby be made as to whether discharge control through the use of a modified drive signal is effective.

### MODIFICATION EXAMPLE 3

In the liquid material discharge method of the first embodiment, the arrangement of the droplet discharge heads 50 with respect to the head unit 9 is not limited as such. For example, the droplet discharge heads 50 may be aligned at an angle with respect to the X-axis direction. Finer droplets can thereby be landed in the primary scanning direction.

### MODIFICATION EXAMPLE 4

In the wiring substrate manufacturing method of the first embodiment, the arrangement of the wiring 301, 303 is not limited as such. The liquid material discharge method of the present invention can also be applied to a multilayer wiring substrate in which wiring is layered on the insulation film 307.

### MODIFICATION EXAMPLE 5

In the color filter manufacturing method of the second embodiment, the arrangement of the color layers 505R, 505G, 505B is not limited as such. The liquid material discharge method of the present invention can be applied to a striped arrangement as well as to a mosaic arrangement or a delta arrangement.

### MODIFICATION EXAMPLE 6

In the color filter manufacturing method of the second embodiment, the color layers 505 are not limited to three colors. For example, the liquid material discharge method of the present invention can also be applied in a multicolor color filter in which complementary colors and other colors besides the RGB colors are combined.

### MODIFICATION EXAMPLE 7

In the method for manufacturing the luminescent element part 603 as the organic EL element of the third embodiment, the luminescent element part 603 is not limited to multicolored light emission. For example, it is possible to adopt a configuration in which the luminescent element part 603 emits white light, and a color filter is provided on the side of the sealing substrate 620, or a configuration in which a color filter is provided on the side of the element substrate 601.

### MODIFICATION EXAMPLE 8

The liquid material discharge method of the first embodiment can be applied not only for manufacturing metal wiring, color filters, and organic EL elements, but also as a method for forming fluorescent elements, electron-emitting elements, and various other types of functional elements.

### General Interpretation of Terms

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A liquid material discharge method comprising:
positioning a substrate and a discharge head having a plurality of nozzles to face each other;
discharging droplets of a liquid material including a functional material onto the substrate in synchronization with a primary scanning for moving the discharge head and the substrate in relative manner; and
varying a discharge timing for discharging the droplets from at least one of the nozzles based on landing position information of the droplets that are discharged from the nozzles.

2. The liquid material discharge method according to claim 1, further comprising
acquiring the landing position information of the droplets that are discharged from the nozzles by driving the discharge head.

3. The liquid material discharge method according to claim 1, further comprising
generating a first arrangement pattern, based on which the discharging of the droplets of the liquid material onto the substrate in synchronization with the primary scanning is performed, and a second arrangement pattern in which flying deflection is corrected with respect to the first arrangement pattern in a direction of the primary scanning,
the varying of the discharge timing including varying the discharge timing for discharging droplets from the at least one of the nozzles in which the flying deflection occurs based on the second arrangement pattern.

4. The liquid material discharge method according to claim 3, wherein
the generating of the second arrangement pattern includes generating the second arrangement pattern for a reverse movement in the primary scanning and generating the second arrangement pattern for a forward movement in the primary scanning by correcting the flying deflection in the primary scanning direction differently for the reverse movement and the forward movement to generate the second arrangement patterns.

5. The liquid material discharge method according to claim 3, wherein
the varying of the discharge timing includes correcting the discharge timing in the primary scanning direction to compensate for the flying deflection in units of discharge resolution at which the droplets are discharged on the substrate.

6. The liquid material discharge method according to claim 3, wherein
the varying of the discharge timing includes correcting the discharge timing in the primary scanning direction to compensate for the flying deflection in units of movement resolution of a movement mechanism for moving the substrate in the primary scanning direction.

7. The liquid material discharge method according to claim 1, further comprising
providing a plurality of discharge regions partitioned by a plurality of partition wall parts on the substrate,
the varying of the discharge timing includes varying the discharge timing so that at least a portion of the droplets discharged from the at least one of the nozzles in which the flying deflection occurs based on the landing position information does not land on the partition wall parts or so that the droplets do not land in the vicinity of the partition wall parts.

8. A wiring substrate manufacturing method comprising:
discharging the liquid material including a conductive material using the liquid material discharge method according to claim 1 to form a wiring pattern on the substrate; and
drying and baking the liquid material discharged onto the substrate in the wiring pattern to form a wiring on the substrate.

9. A color filter manufacturing method comprising:
discharging the liquid material including coloring materials with at least three colors onto a plurality of color regions on the substrate partitioned by a plurality of partition wall parts using the liquid material discharge method according to claim 1; and
drying the liquid material discharged onto the substrate to form color layers with the at least three colors disposed in corresponding color regions on the substrate.

10. An organic EL element manufacturing method comprising:
discharging the liquid material including at least a luminescent-layer-forming material onto a plurality of luminescent layer formation regions on the substrate partitioned by a plurality of partition wall parts using the liquid material discharge method according to claim 1; and
drying the liquid material discharged onto the substrate to form organic EL luminescent layers disposed in corresponding luminescent layer formation regions on the substrate.

11. A liquid material discharge method comprising:
positioning a substrate and a discharge head having a plurality of nozzles to face each other;
discharging droplets of a liquid material including a functional material onto the substrate in synchronization with a primary scanning for moving the discharge head and the substrate in relative manner; and
varying a discharge rate for discharging the droplets from at least one of the nozzles based on landing position information of the droplets that are discharged from the nozzles.

12. The liquid material discharge method according to claim 11, further comprising
acquiring the landing position information of the droplets that are discharged from the nozzles by driving the discharge head.

13. The liquid material discharge method according to claim 11, further comprising
generating a first arrangement pattern, based on which the discharging of the droplets of the liquid material onto the substrate in synchronization with the primary scanning is performed, and a second arrangement pattern in which flying deflection is corrected with respect to the first arrangement pattern in a direction of the primary scanning,
the varying of the discharge rate including varying the discharge rate for discharging droplets from the at least one of the nozzles in which the flying deflection occurs based on the second arrangement pattern.

14. The liquid material discharge method according to claim 13, wherein
the generating of the second arrangement pattern includes generating the second arrangement pattern for a reverse movement in the primary scanning and generating the second arrangement pattern for a forward movement in the primary scanning by correcting the flying deflection in the primary scanning direction differently for the reverse movement and the forward movement to generate the second arrangement patterns.

15. The liquid material discharge method according to claim 11, wherein
providing a plurality of discharge regions partitioned by a plurality of partition wall parts on the substrate,
the varying of the discharge rate includes varying the discharge rate so that at least a portion of the droplets discharged from the at least one of the nozzles in which the flying deflection occurs based on the landing position information does not land on the partition wall parts or so that the droplets do not land in the vicinity of the partition wall parts.

16. A wiring substrate manufacturing method comprising:
discharging the liquid material including a conductive material using the liquid material discharge method according to claim 11 to form a wiring pattern on the substrate; and
drying and baking the liquid material discharged onto the substrate in the wiring pattern to form a wiring on the substrate.

17. A color filter manufacturing method comprising:
discharging the liquid material including coloring materials with at least three colors onto a plurality of color regions on the substrate partitioned by a plurality of partition wall parts using the liquid material discharge method according to claim 11; and
drying the liquid material discharged onto the substrate to form color layers with the at least three colors disposed in corresponding color regions on the substrate.

18. An organic EL element manufacturing method comprising:
discharging the liquid material including at least a luminescent-layer-forming material onto a plurality of luminescent layer formation regions on the substrate partitioned by a plurality of partition wall parts using the liquid material discharge method according to claim 11; and
drying the liquid material discharged onto the substrate to form organic EL luminescent layers disposed in corresponding luminescent layer formation regions on the substrate.
